(19) United States
(12) Patent Application Publication
(10) Pub. No.: US 2023/0395741 A1
(43) Pub. Date: Dec. 7, 2023

(54) High Dynamic-Range Spad Devices

(71) Applicant: Ouster, Inc., San Francisco, CA (US)

(72) Inventors: Tarek Al Abbas, Edinburgh (GB); Laurence Stark, Edinburgh (GB); Neil Calder, Edinburgh (GB); Robert Henderson, Edinburgh (GB)

(73) Assignee: Ouster, Inc., San Francisco, CA (US)

(21) Appl. No.: 18/234,569

(22) Filed: Aug. 16, 2023

Related U.S. Application Data
(60) Provisional application No. 63/398,731, filed on Aug. 17, 2022.

(51) Int. Cl. H01L 31/107; G01S 7/4865; G01S 17/89; H01L 31/18

(52) U.S. Cl. CPC H01L 31/107; G01S 7/4865; G01S 17/89; H01L 31/18

(57) ABSTRACT

Circuits, methods, and apparatus that can provide detector arrays that are able to avoid or limit saturation of SPAD devices from both ambient and reflected light while maintaining sufficient sensitivity to generate a lidar image. An example can provide a SPAD device having high dynamic range. This SPAD device can include a first cathode for a first diode and a second cathode for a second diode formed in a common anode, where the common anode can be formed of an epitaxial layer. When high sensitivity is desired, both the first diode and the second diode can be biased above their breakdown voltage. When a lower sensitivity is desired, the first diode can be biased above its breakdown voltage while the second diode can be biased below its breakdown voltage. Diode bias voltages can be tuned to steer photogenerated carriers towards the second cathode to further reduce sensitivity.

### CROSS-REFERENCES TO RELATED APPLICATIONS

The present application claims the benefit of and priority to U.S. provisional application 63/398,731, filed Aug. 17, 2022, which is incorporated by reference.

### BACKGROUND

This disclosure relates generally to lidar systems and more specifically to adjusting the sensitivity of SPAD devices in a sensor array.

Time-of-flight (ToF) based imaging is used in a number of applications, including range finding, depth profiling, and 3D imaging, such as light imaging, detection, and ranging (LiDAR, or lidar). Direct time-of-flight (dToF) measurement includes directly measuring the length of time between emitting radiation from emitter elements and sensing the radiation by detector elements after reflection from an object or other target. The distance to the target can be determined from the measured length of time. Indirect time-of-flight measurement includes determining the distance to the target by phase modulating the amplitude of the signals emitted by the emitter elements of the lidar system and measuring phases (e.g., with respect to delay or shift) of the echo signals received at the detector elements of the lidar system. These phases can be measured with a series of separate measurements or samples.

In specific applications, the sensing of the reflected radiation in either direct or indirect time-of-flight systems can be performed using an array of detectors, such as an array of Single-Photon Avalanche Diodes (SPADs). One or more detectors can define a sensor for a pixel, where a sensor array can be used to generate a lidar image for the depth (range) to objects for respective pixels.

When imaging a scene, these sensors, which can also be referred to as ToF sensors or photosensors, can include circuits that time-stamp and count incident photons as reflected from a target. Data rates can be compressed by histogramming timestamps. For instance, for each pixel, a histogram having bins (also referred to as “time bins”) corresponding to different ranges of photon arrival times can be stored in memory, and photon counts can be accumulated in different time bins of the histogram according to their arrival time. A time bin can correspond to a time range of, e.g., 1 ns, 2 ns, or the like. Some lidar systems can perform in-pixel histogramming of incoming photons using a clock-driven architecture and a limited memory block, which can provide a significant increase in histogramming capacity. However, since memory capacity is limited and typically cannot cover the desired distance range at once, such lidar systems can operate in “strobing” mode. “Strobing” refers to the generation of detector control signals (also referred to herein as “strobe signals” or “strobes”) to control the timing and/or duration of activation (also referred to herein as “detection windows” or “strobe windows”) of one or more detectors of the lidar system, such that photon detection and histogramming is performed sequentially over a set of different time windows, each corresponding to an individual distance subrange, so as to collectively define the entire distance range. In other words, partial histograms can be acquired for subranges or “time slices” corresponding to different sub-ranges of the distance range and then amalgamated into one full-range histogram. Thousands of time bins (each corresponding to respective photon arrival times) can typically be used to form a histogram sufficient to cover the typical time range of a lidar system (e.g., microseconds) with the typical time-to-digital converter (TDC) resolution (e.g., 50 to 100 picoseconds).

Reflected light from the emitter elements can be received using a detector array. The detector array can be an array of SPADs for an array of pixels, also referred to as channels, where each pixel includes one or more SPADs. These SPADs can work in conjunction with other circuits, such as address generators, accumulation logic, memory circuits, and the like, to generate a lidar image.

The SPADs in a detector array can also receive photons from ambient light, such as solar radiation or other light source in the environment. Under some conditions, this ambient light can provide enough photons to saturate SPADs in a first portion of a detector array. That is, SPADs in the first portion of the array can become saturated due to ambient light such that their corresponding bin counts can remain at or near a maximum level. When this saturation occurs, reflected light from the emitter elements can be difficult to detect and image information can be lost. To avoid saturation by ambient light, an f-stop of an aperture that allows light to reach the detector array can be increased. This increase in f-stop can block some of the ambient light from reaching the SPADs in the first portion of the detector array and can help to reduce some SPAD saturation. Unfortunately, the increase in f-stop can also block light from reaching SPADs in a second portion of the detector array, thereby causing a loss of detail in corresponding portions of the resulting lidar image.

Also, the intensity of light from the emitter elements that is reflected to the detector array can vary greatly. For example, a first object at a distance might reflect minimal light, thus making a low f-stop desirable. Other objects can be closer or have a higher reflectivity. Under these conditions, particularly when an aperture for the detector array is set with a low f-stop, high-intensity reflected light can be received by SPADs in a first portion of a detector array. Such an intensity of light can again saturate SPADs in the first portion of detector array. When this occurs, information regarding a reflectivity of an object can be lost. For example, it might be known that an object has at least a certain level of reflectivity, but the actual level of reflectivity for the object might not be quantifiable. As before, an f-stop of an aperture that allows light to reach the detector array might be increased. This increase in f-stop can block some of the reflected light from reaching SPADs in the first portion of the detector array and can help to reduce some SPAD saturation. Unfortunately, the increase in f-stop can also block light from reaching SPADs in a second portion of the detector array, again causing a loss of detail in corresponding portions of the resulting lidar image.

Thus, what is needed are circuits, methods, and apparatus that can provide detector arrays that are able to avoid or limit saturation of SPADs from both ambient and reflected light while maintaining sufficient sensitivity to generate a lidar image.

### SUMMARY

Accordingly, embodiments of the present invention can provide circuits, methods, and apparatus that can provide detector arrays that are able to avoid or limit saturation of SPAD devices from both ambient and reflected light while maintaining sufficient sensitivity to generate a lidar image. An illustrative embodiment of the present invention can provide a SPAD device having a high dynamic range. This SPAD device can have a first cathode for a first diode and a second cathode for a second diode implanted or diffused in a common anode formed of an epitaxial layer. When high sensitivity is desired, both the first diode and the second diode can be biased above their breakdown voltage. When a lower sensitivity is desired, the first diode can be biased above its breakdown voltage while the second diode can be biased below its breakdown voltage. In this biasing configuration, some photogenerated carriers in the common anode can reach the second cathode where it might be less likely to start an avalanche, while other photogenerated carriers in the common anode can reach the multiplication region of the first cathode where it might be more likely to start an avalanche. The photogenerated carriers in the common anode can be steered away from the multiplication region of the first cathode by varying amounts that can be tuned by varying the bias voltages across the first diode and the second diode.

These SPAD devices can be arranged in various configurations in these and other embodiments of the present invention. For example, the first cathode region can be formed to have a surface profile of a disk, while the second cathode region can be formed to have an annular surface profile positioned around the first cathode region. The first and second cathode regions can be separated by a first guard ring. A second guard ring can be formed around the first and second cathode regions. A deep trench isolation channel can be formed around the SPAD device. In another example, the second cathode region can have a notched rectangular shape, where the first diode is located in the notch. A guard ring can be formed around and between the first cathode region and the second cathode region. A deep trench isolation channel can be formed around the SPAD device.

Various embodiments of the present invention can incorporate one or more of these and the other features described herein. A better understanding of the nature and advantages of the present invention can be gained by reference to the following detailed description and the accompanying drawings.

### BRIEF DESCRIPTION OF THE DRAWINGS

FIG. 1 is a simplified block diagram of a lidar system according to some embodiments;

FIG. 2 is a simplified block diagram of components of a time-of-flight measurement system or circuit according to some embodiments;

FIG. 3 illustrates the operation of a typical lidar system that can be improved by embodiments;

FIG. 4 shows a histogram according to embodiments of the present invention;

FIG. 5 shows the accumulation of a histogram over multiple pulse trains for a selected pixel according to embodiments of the present invention;

FIG. 6 illustrates an example of a pixel according to an embodiment of the present invention;

FIG. 7 illustrates a circuit for setting a sensitivity of one or more SPAD devices using ambient light according to an embodiment of the present invention;

FIGS. 8A and 8B are flowcharts for setting a sensitivity of one or more SPAD devices using ambient light according to an embodiment of the present invention;

FIG. 9 illustrates a circuit for setting a sensitivity of one or more SPAD devices using partial time-of-flight data according to an embodiment of the present invention;

FIGS. 10A and 10B are flowcharts for setting a sensitivity of one or more SPAD devices using partial time-of-flight data according to an embodiment of the present invention;

FIGS. 11A through 11C illustrate histogram data that can be used for setting a sensitivity of one or more SPAD devices using partial time-of-flight data according to an embodiment of the present invention;

FIG. 12 illustrates a top view of a SPAD device structure according to an embodiment of the present invention;

FIG. 13 illustrates a circuit for tuning a sensitivity of a SPAD device according to an embodiment of the present invention;

FIG. 14 illustrates a cross-section of a SPAD device according to an embodiment of the present invention;

FIG. 15 is another cross-section view of a SPAD device according to an embodiment of the present invention;

FIG. 16 illustrates another circuit for tuning a sensitivity of a SPAD device according to an embodiment of the present invention;

FIG. 17 illustrates a surface profile of another SPAD device according to an embodiment of the present invention; and

FIG. 18 is a simplified illustration of an automobile in which multiple solid-state flash lidar sensors according to some embodiments are included at different locations along the vehicle.

### DETAILED DESCRIPTION

Embodiments of the present invention can provide circuits, methods, and apparatus that provide SPAD devices having a high dynamic range. An example can provide a SPAD device having a first cathode for a first diode and a second cathode for a second diode formed in a common anode, where the common anode can be formed of an epitaxial layer. When high sensitivity is desired, both the first diode and the second diode can be biased above their breakdown voltage. When a lower sensitivity is desired, the first diode can be biased above its breakdown voltage while the second diode can be biased below its breakdown voltage. Diode bias voltages can be tuned to steer photogenerated carriers towards the second cathode to further reduce sensitivity.

### 1. Example Lidar System

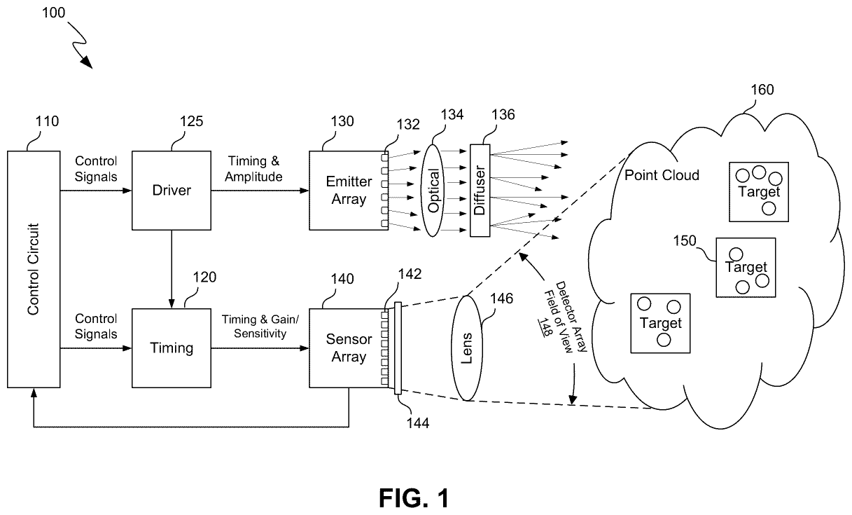

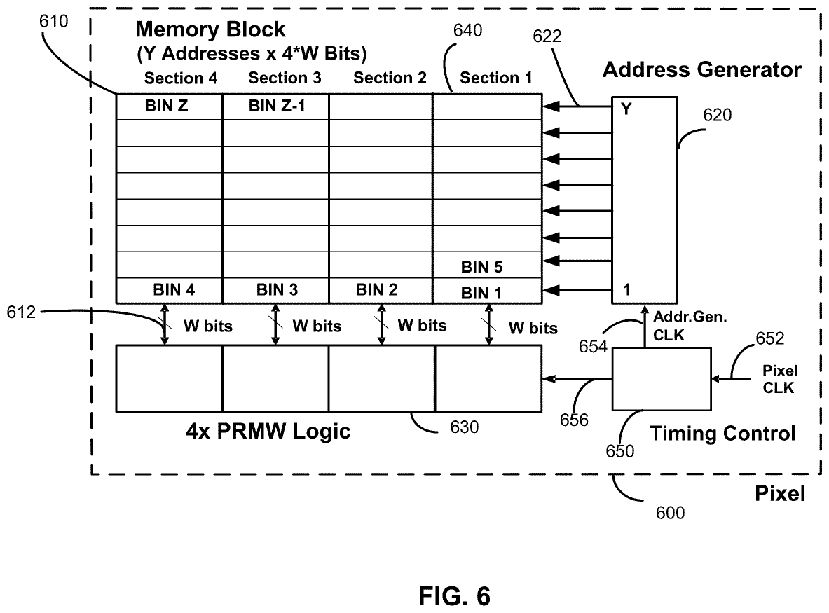

FIG. 1 illustrates an example light-based 3D sensor system 100, such as a Light Detection and Ranging (LiDAR, or lidar) system, in accordance with some embodiments of the invention. Lidar system 100 can include a control circuit 110, a timing circuit 120, driver circuitry 125, an emitter array 130 and a sensor array 140. Emitter array 130 can include a plurality of emitter units 132 arranged in an array (e.g., a one- or two-dimensional array) and sensor array 140 can include a plurality of sensors 142 arranged in an array (e.g., a one- or two-dimensional array). The sensors 142 can be depth sensors, such as time-of-flight (ToF) sensors. In some embodiments each sensor 142 can include, for example, one or more single-photon detectors, such as Single-Photon Avalanche Diodes (SPADs). In some embodiments, each sensor 142 can be coupled to an in-pixel memory block 610 (shown in FIG. 6) that accumulates histogram data for that sensor 142, and the combination of a sensor and in-pixel memory circuitry is sometimes referred to as a “pixel” 142. Each emitter unit 132 of the emitter array 130 can include one or more emitter elements that can emit a radiation pulse (e.g., light pulse) or continuous wave signal at a time and frequency controlled by a timing generator or driver circuitry 125. In some embodiments, the emitter units 132 can be pulsed light sources, such as LEDs or lasers such as vertical cavity surface emitting lasers (VCSELs) that emit a cone of light (e.g., infrared light) having a predetermined beam divergence.

Emitter array 130 can project pulses of radiation into a field of view of the lidar system 100. Some of the emitted radiation can then be reflected back from objects in the field, such as targets 150. The radiation that is reflected back can then be sensed or detected by the sensors 142 within the sensor array 140. Control circuit 110 can implement a processor that measures and/or calculates the distance to targets 150 based on data (e.g., histogram data) provided by sensors 142. In some embodiments control circuit 110 can measure and/or calculate the time of flight of the radiation pulses over the journey from emitter array 130 to target 150 and back to the sensors 142 within the sensor array 140 using direct or indirect time-of-flight (ToF) measurement techniques.

In some embodiments, emitter array 130 can include an array (e.g., a one- or two-dimensional array) of emitter units 132 where each emitter unit is a unique semiconductor chip having one or more individual VCSELs (sometimes referred to herein as emitter elements) formed on the chip. An optical element 134 and a diffuser 136 can be disposed in front of the emitter units such that light projected by the emitter units passes through the optical element 134 (which can include, e.g., one or more Fresnel lenses) and then through diffuser 136 prior to exiting lidar system 100. In some embodiments, optical element 134 can be an array of lenses or lenslets (in which case the optical element 134 is sometimes referred to herein as “lens array 134” or “lenslet array 134”) that collimate or reduce the angle of divergence of light received at the array and pass the altered light to diffuser 136. The diffuser 136 can be designed to spread light received at the diffuser over an area in the field that can be referred to as the field of view of the emitter array (or the field of illumination of the emitter array). In general, in these embodiments, emitter array 130, lens array or optical element 134, and diffuser 136 cooperate to spread light from emitter array 130 across the entire field of view of the emitter array. A variety of emitters and optical components can be used.

The driver circuitry 125 can include one or more driver circuits, each of which controls one or more emitter units. The driver circuits can be operated responsive to timing control signals with reference to a master clock and/or power control signals that control the peak power and/or the repetition rate of the light output by the emitter units 132. In some embodiments, each of the emitter units 132 in the emitter array 130 is connected to and controlled by a separate circuit in driver circuitry 125. In other embodiments, a group of emitter units 132 in the emitter array 130 (e.g., emitter units 132 in spatial proximity to each other or in a common column of the emitter array), can be connected to a same circuit within driver circuitry 125. Driver circuitry 125 can include one or more driver transistors configured to control the modulation frequency, timing, and/or amplitude of the light (optical emission signals) output from the emitter units 132.

In some embodiments, a single event of emitting light from the multiple emitter units 132 can illuminate an entire image frame (or field of view); this is sometimes referred to as a “flash” lidar system. Other embodiments can include non-flash or scanning lidar systems, in which different emitter units 132 emit light pulses at different times, e.g., into different portions of the field of view. The maximum optical power output of the emitter units 132 can be selected to generate a signal-to-noise ratio of the echo signal from the farthest, least reflective target at the brightest background illumination conditions that can be detected in accordance with embodiments described herein. In some embodiments, an optical filter (not shown) such as a bandpass filter can be included in the optical path of the emitter units 132 to control the emitted wavelengths of light.

Light output from the emitter units 132 can impinge on and be reflected back to lidar system 100 by one or more targets 150 in the field. The reflected light can be detected as an optical signal (also referred to herein as a return signal, echo signal, or echo) by one or more of the sensors 142 (e.g., after being collected by receiver optics 146), converted into an electrical signal representation (sometimes referred to herein as a detection signal), and processed (e.g., based on time-of-flight techniques) to define a 3-D point cloud representation 160 of a field of view 148 of the sensor array 140. In some embodiments, operations of lidar systems can be performed by one or more processors or controllers, such as control circuit 110.

Sensor array 140 includes an array of sensors 142. In some embodiments, each sensor 142 can include one or more photodetectors, e.g., SPADs. And in some particular embodiments, sensor array 140 can be a very large array made up of hundreds of thousands or even millions of densely packed SPADs. Receiver optics 146 and receiver electronics (including timing circuit 120) can be coupled to the sensor array 140 to power, enable, and disable all or parts of the sensor array 140 and to provide timing signals thereto. In some embodiments, sensors 142 can be activated or deactivated with at least nanosecond precision (supporting time bins of 1 ns, 2 ns, etc.), and in various embodiments, sensors 142 can be individually addressable, addressable by group, and/or globally addressable. The receiver optics 146 can include a bulk optic lens that is configured to collect light from the largest field of view that can be imaged by the lidar system 100, which in some embodiments is determined by the aspect ratio of the sensor array 140 combined with the focal length of the receiver optics 146.

In some embodiments, the receiver optics 146 can further include various lenses (not shown) to improve the collection efficiency of the sensors and/or an anti-reflective coating (also not shown) to reduce or prevent detection of stray light. In some embodiments, a spectral filter 144 can be positioned in front of the sensor array 140 to pass or allow passage of “signal” light (i.e., light of wavelengths corresponding to wavelengths of the light emitted from the emitter units) but substantially reject or prevent passage of non-signal light (i.e., light of wavelengths different from the wavelengths of the light emitted from the emitter units).

The sensors 142 of sensor array 140 are connected to the timing circuit 120. The timing circuit 120 can be phase-locked to the driver circuitry 125 of emitter array 130. The sensitivity of each of the sensors 142 or of groups of sensors 142 can be controlled. For example, when the detector elements include reverse-biased photodiodes, avalanche photodiodes (APD), PIN diodes, and/or Geiger-mode avalanche diodes (e.g., SPADs), the reverse bias can be adjusted. In some embodiments, a higher overbias provides higher sensitivity.

In some embodiments, control circuit 110, which can be, for example, a microcontroller or microprocessor, provides different emitter control signals to the driver circuitry 125 of different emitter units 132 and/or provides different signals (e.g., strobe signals) to the timing circuit 120 of different sensors 142 to enable/disable the different sensors 142 to detect the echo signal (or returning light) from the target 150. The control circuit 110 can also control memory storage operations for storing data indicated by the detection signals in a non-transitory memory or memory array that is included therein or is distinct therefrom.

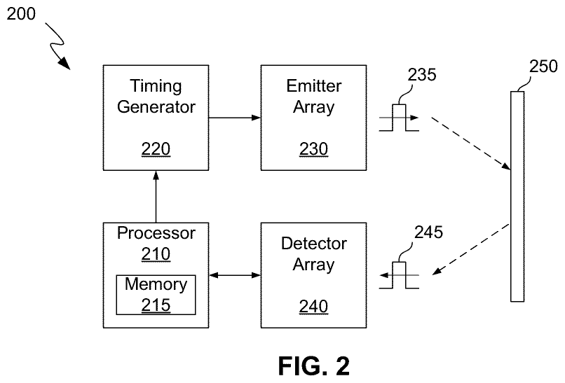

FIG. 2 further illustrates components of a ToF measurement system or circuit 200 in a lidar application in accordance with some embodiments described herein. The circuit 200 can include a processor circuit 210 (such as a digital signal processor (DSP)), a timing generator 220 that controls timing of the illumination source (illustrated by way of example with reference to a laser emitter array 230), and an array of sensors (illustrated by way of example with reference to a sensor array 240). The processor circuit 210 can also include a sequencer circuit (not shown in FIG. 2) that is configured to coordinate operation of emitter units within the illumination source (emitter array 230) and sensors within the sensor array 240.

The processor circuit 210 and the timing generator 220 can implement some of the operations of the control circuit 110 and the driver circuitry 125 of FIG. 1. Similarly, emitter array 230 and sensor array 240 can be representative of emitter array 130 and sensor array 140 in FIG. 1. The laser emitter array 230 can emit laser pulses 235 at times controlled by the timing generator 220. Light 245 from the laser pulses 235 can be reflected back from a target (illustrated by way of example as object 250) and can be sensed by sensor array 240. The processor circuit 210 implements a pixel processor that can measure or calculate the time of flight of each laser pulse 235 and its reflected light 245 over the journey from emitter array 230 to object 250 and back to the sensor array 240.

The processor circuit 210 can provide analog and/or digital implementations of logic circuits that provide the necessary timing signals (such as quenching and gating or strobe signals) to control operation of the single-photon detectors of the sensor array 240 and that process the detection signals output therefrom. For example, individual single-photon detectors of sensor array 240 can be operated such that they generate detection signals in response to incident photons only during the gating intervals or strobe windows that are defined by the strobe signals, while photons that are incident outside the strobe windows have no effect on the outputs of the single-photon detectors. More generally, the processor circuit 210 can include one or more circuits that are configured to generate detector control signals that control the timing and/or durations of activation of the sensors 142 (or particular single-photon detectors therein), and/or to generate respective emitter control signals that control the output of light from the emitter units 132.

Detection events can be identified by the processor circuit 210 based on one or more photon counts indicated by the detection signals output from the sensor array 240, which can be stored in a non-transitory memory 215. In some embodiments, the processor circuit 210 can include a correlation circuit or correlator that identifies detection events based on photon counts (referred to herein as correlated photon counts) from two or more single-photon detectors within a predefined window (time bin) of time relative to one another, referred to herein as a correlation window or correlation time, where the detection signals indicate arrival times of incident photons within the correlation window. Since photons corresponding to the optical signals output from the emitter array 230 (also referred to as signal photons) can arrive relatively close in time with each other, as compared to photons corresponding to ambient light (also referred to as background photons), the correlator can be configured to distinguish signal photons based on respective times of arrival being within the correlation time relative to one another. Such correlators and strobe windows are described, for example, in U.S. Patent Application Publication No. 2019/0250257, entitled “Methods and Systems for High-Resolution Long Range Flash Lidar,” which is incorporated by reference herein in its entirety for all purposes.

The processor circuit 210 can be small enough to allow for three-dimensionally stacked implementations, e.g., with the sensor array 240 “stacked” on top of processor circuit 210 (and other related circuits) that is sized to fit within an area or footprint of the sensor array 240. For example, some embodiments can implement the sensor array 240 on a first substrate, and transistor arrays of the processor circuit 210 on a second substrate, with the first and second substrates/wafers bonded in a stacked arrangement, as described for example in U.S. Patent Application Publication No. 2020/0135776, entitled “High Quantum Efficiency Geiger-Mode Avalanche Diodes Including High Sensitivity Photon Mixing Structures and Arrays Thereof,” the disclosure of which is incorporated by reference herein in its entirety for all purposes.

The pixel processor implemented by the processor circuit 210 can be configured to calculate an estimate of the average ToF aggregated over hundreds or thousands of laser pulses 235 and photon returns in reflected light 245. The processor circuit 210 can be configured to count incident photons in the reflected light 245 to identify detection events (e.g., based on one or more SPADs within the sensor array 240 that have been “triggered”) over a laser cycle (or portion thereof).

The timings and durations of the detection windows can be controlled by a strobe signal (Strobe #i or Strobe<i>). Many repetitions of Strobe #i can be aggregated (e.g., in the pixel) to define a sub-frame for Strobe #i, with subframes i=1 to n defining an image frame. Each sub-frame for Strobe #i can correspond to a respective distance sub-range of the overall imaging distance range. In a single-strobe system, a sub-frame for Strobe #1 can correspond to the overall imaging distance range and is the same as an image frame since there is a single strobe. The time between emitter unit pulses (which defines a laser cycle, or more generally emitter pulse frequency) can be selected to define or can otherwise correspond to the desired overall imaging distance range for the ToF measurement circuit 200. Accordingly, some embodiments described herein can utilize range strobing to activate and deactivate sensors for durations or “detection windows” of time over the laser cycle, at variable delays with respect to the firing of the laser, thus capturing reflected correlated signal photons corresponding to specific distance sub-ranges at each window/frame, e.g., to limit the number of ambient photons acquired in each laser cycle.

The strobing can turn off and on individual photodetectors or groups of photodetectors (e.g., for a pixel), e.g., to save energy during time intervals outside the detection window. For instance, a SPAD or other photodetector can be turned off during idle time, such as after an integration burst of time bins and before a next laser cycle. As another example, SPADs can also be turned off while all or part of a histogram is being read out from non-transitory memory 215. Yet another example is when a counter for a particular time bin reaches the maximum value (also referred to as “bin saturation”) for the allocated bits in the histogram stored in non-transitory memory 215. A control circuit can provide a strobe signal to activate a first subset of the sensors while leaving a second subset of the sensors inactive. In addition or alternatively, circuitry associated with a sensor can also be turned off and on as specified times.

### 2. Detection of Reflected Pulses

The sensors be arranged in a variety of ways for detecting reflected pulses. For example, the sensors can be arranged in an array, and each sensor can include an array of photodetectors (e.g., SPADs). A signal from a photodetector indicates when a photon was detected and potentially how many photons were detected. For example, a SPAD can be a semiconductor photodiode operated with a reverse bias voltage that generates an electric field of a sufficient magnitude that a single charge carrier introduced into the depletion layer of the device can cause a self-sustaining avalanche via impact ionization. The initiating charge carrier can be photo-electrically generated by a single incident photon striking the high field region. The avalanche is quenched by a quench circuit, either actively (e.g., by reducing the bias voltage) or passively (e.g., by using the voltage drop across a serially connected resistor), to allow the device to be “reset” to detect other photons. This single-photon detection mode of operation is often referred to as “Geiger Mode,” and an avalanche can produce a current pulse that results in a photon being counted. Other photodetectors can produce an analog signal (in real time) proportional to the number of photons detected. The signals from individual photodetectors can be combined to provide a signal from the sensor, which can be a digital signal. This signal can be used to generate histograms.

### 2.1. Time-of-Flight Measurements and Detectors

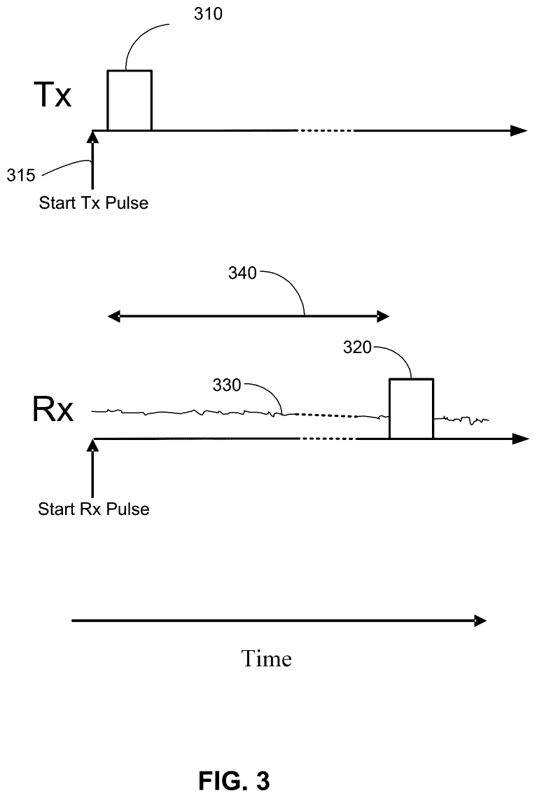

FIG. 3 illustrates the operation of a typical lidar system that can be improved by some embodiments. A laser or other emitter (e.g., within emitter array 230 or emitter array 130) generates a light pulse 310 of short duration. The horizontal axis represents time and the vertical axis represents power. An example laser pulse duration, characterized by the full-width half maximum (FWHM), is a few nanoseconds, with the peak power of a single emitter being around a few watts. Embodiments that use side emitter lasers or fiber lasers can have much higher peak powers, while embodiments with small diameter VCSELs could have peak powers in the tens of milliwatts to hundreds of milliwatts.

A start time 315 for the emission of the pulse does not need to coincide with the leading edge of the pulse. As shown, the leading edge of light pulse 310 can be after the start time 315. One can want the leading edge to differ in situations where different patterns of pulses are transmitted at different times, e.g., for coded pulses. In this example, a single pulse of light is emitted. In some embodiments, a sequence of multiple pulses can be emitted, and the term “pulse train” as used herein refers to either a single pulse or a sequence of pulses.

An optical receiver system (which can include, e.g., sensor array 240 or sensor array 140) can start detecting received light at the same time as the laser is started, i.e., at the start time. In other embodiments, the optical receiver system can start at a later time, which is at a known time after the start time for the pulse. The optical receiver system detects background light 330 initially and after some time detects the laser pulse reflection 320. The optical receiver system can compare the detected light intensity against a threshold to identify the laser pulse reflection 320. Where a sequence of pulses is emitted, the optical receiver system can detect each pulse. The threshold can distinguish the background light 330 from light corresponding to the laser pulse reflection 320.

The time-of-flight 340 is the time difference between the pulse 310 being emitted and the pulse reflection 320 being received. The time difference can be measured by subtracting the emission time of the pulse 310 (e.g., as measured relative to the start time) from a received time of the pulse reflection 320 (e.g., also measured relative to the start time). The distance to the target can be determined as half the product of the time-of-flight and the speed of light. Pulses from the laser device reflect from objects in the scene at different times, depending on start time and distance to the object, and the sensor array detects the pulses of reflected light.

2.2. Histogram Signals from Photodetectors

One mode of operation of a lidar system is time-correlated single photon counting (TCSPC), which is based on counting single photons in a periodic signal. This technique works well for low levels of periodic radiation which is suitable in a lidar system. This time correlated counting can be controlled by a periodic signal, e.g., from timing generator 220.

The frequency of the periodic signal can specify a time resolution within which data values of a signal are measured. For example, one measured value can be obtained for each photosensor per cycle of the periodic signal. In some embodiments, the measurement value can be the number of photodetectors that triggered during that cycle. The time period of the periodic signal corresponds to a time bin, with each cycle being a different time bin.

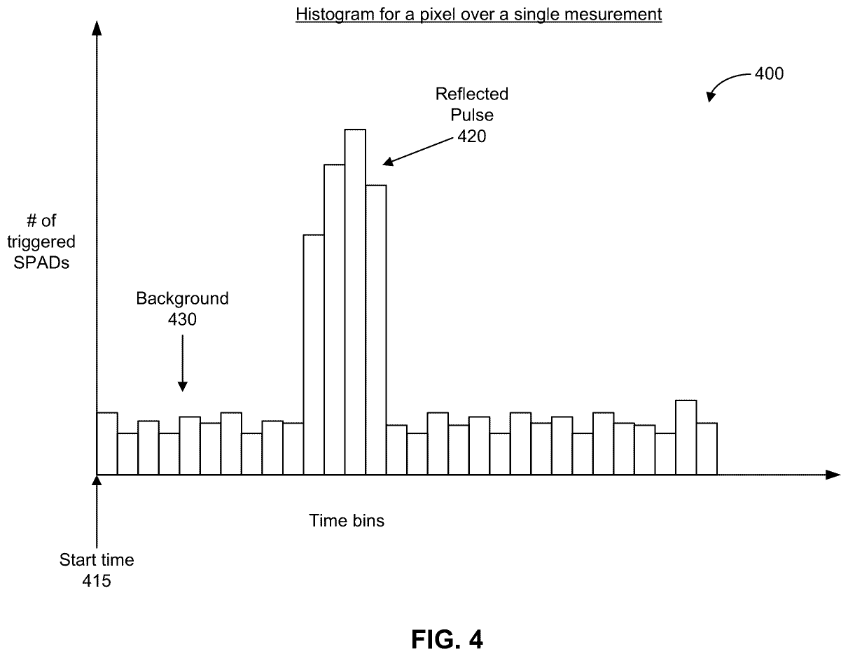

FIG. 4 shows a histogram 400 according to some embodiments described herein. The horizontal axis corresponds to time bins as measured relative to start time 415. As described above, start time 415 can correspond to a start time for an emitted pulse train. Any offsets between rising edges of the first pulse of a pulse train and the start time for either or both of a pulse train and a detection time interval can be accounted for when determining the received time to be used for the time-of-flight measurement. In this example, the sensor pixel includes a number of SPADs, and the vertical axis corresponds to the number of triggered SPADs for each time bin. Other types of photodetectors can also be used. For instance, in embodiments where APDs are used as photodetectors, the vertical axis can correspond to an output of an analog-to-digital converter (ADC) that receives the analog signal from an APD. It is noted that APDs and SPADS can both exhibit saturation effects. Where SPADs are used, a saturation effect can lead to dead time for the pixel (e.g., when all SPADs in the pixel are immediately triggered and no SPADs can respond to later-arriving photons). Where APDs are used, saturation can result in a constant maximum signal rather than the dead-time based effects of SPADs. Some effects can occur for both SPADs and APDs, e.g., pulse smearing of very oblique surfaces can occur for both SPADs and APDs.

The counts of triggered SPADs for each of the time bins correspond to the different bars in histogram 400. The counts at the early time bins are relatively low and correspond to background noise 430. At some point, a reflected pulse 420 is detected. The corresponding counts are much larger and can be above a threshold that discriminates between background and a detected pulse. The reflected pulse 420 results in increased counts in four time bins, which might result from a laser pulse of a similar width, e.g., a 4 ns pulse when time bins are each 1 ns.

The temporal location of the time bins corresponding to reflected pulse 420 can be used to determine the received time, e.g., relative to start time 415. In some embodiments, matched filters can be used to identify a pulse pattern, thereby effectively increasing the signal-to-noise ratio and allowing a more accurate determination of the received time. In some embodiments, the accuracy of determining a received time can be less than the time resolution of a single time bin. For instance, for a time bin of 1 ns, a resolution of one time bin would correspond to a distance about 15 cm. However, it can be desirable to have an accuracy of only a few centimeters.

Accordingly, a detected photon can result in a particular time bin of the histogram being incremented based on its time of arrival relative to a start signal, e.g., as indicated by start time 415. The start signal can be periodic such that multiple pulse trains are sent during a measurement. Each start signal can be synchronized to a laser pulse train, with multiple start signals causing multiple pulse trains to be transmitted over multiple laser cycles (also sometimes referred to as “shots”). Thus, a time bin (e.g., from 200 to 201 ns after the start signal) would occur for each detection interval. The histogram can accumulate the counts, with the count of a particular time bin corresponding to a sum of the measured data values all occurring in that particular time bin across multiple shots. When the detected photons are histogrammed based on such a technique, the result can be a return signal having a signal to noise ratio greater than that from a single pulse train by the square root of the number of shots taken.

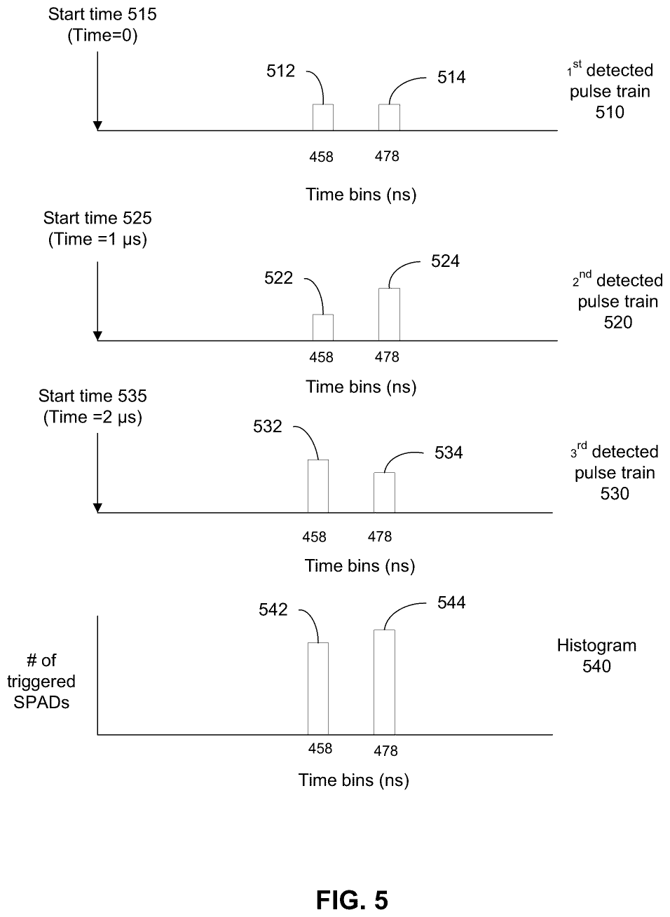

FIG. 5 shows the accumulation of a histogram over multiple pulse trains for a selected pixel according to some embodiments described herein. FIG. 5 shows three detected pulse trains 510, 520 and 530. Each detected pulse train corresponds to a transmitted pulse train that has a same pattern of two pulses separated by a same amount of time. Thus, each detected pulse train has a same pulse pattern, as shown by two time bins having an appreciable value. Counts for other time bins are not shown for simplicity of illustration, although the other time bins can have non-zero values (generally lower than the values in time bins corresponding to detected pulses).

In the first detected pulse train 510, the counts for time bins 512 and 514 are the same. This can result from a same (or approximately the same) number of photodetectors detecting a photon during each of the two time bins, or approximately the same number of photons being detected during the two time bins, depending on the particular photodetectors used. In other embodiments, more than one consecutive time bin can have a non-zero value; but for ease of illustration, individual nonzero time bins have been shown.

Time bins 512 and 514 respectively occur 458 ns and 478 ns after start time 515. The displayed counters for the other detected pulse trains occur at the same time bins relative to their respective start times. In this example, start time 515 is identified as occurring at time 0, but the actual time is arbitrary. The first detection interval for the first detected pulse train can be 1 μs. Thus, the number of time bins measured from start time 515 can be 1,000. After, this first detection interval ends, a new pulse train can be transmitted and detected. The start and end of the different time bins can be controlled by a clock signal, which can be part circuitry that acts as a time-to-digital converter (TDC).

For the second detected pulse train 520, the start time 525 is at 1 μs, at which time the second pulse train can be emitted. Time between start time 515 and start time 525 can be long enough that any pulses transmitted at the beginning of the first detection interval would have already been detected, and thus not cause confusion with pulses detected in the second detection interval. For example, if there is not extra time between shots, then the circuitry could confuse a retroreflective stop sign at 200 m with a much less reflective object at 50 m (assuming a shot period of about 1 us). The two detection time intervals for pulse trains 510 and 520 can be the same length and have the same relationship to the respective start time. Time bins 522 and 524 occur at the same relative times of 458 ns and 478 ns as time bins 512 and 514. Thus, when the accumulation step occurs, the corresponding counters can be added. For instance, the counter values at time bin 512 and 522 can be added together.

For the third detected pulse train 530, the start time 535 is at 2 μs, at which time the third pulse train can be emitted. Time bin 532 and 534 also occur at 458 ns and 478 ns relative to start time 535. The counts for corresponding pulses of different pulse trains can have different values even though the emitted pulses have a same power, e.g., due to the stochastic nature of the scattering process of light pulses off of objects.

Histogram 540 shows an accumulation of the counts from three detected pulse trains 510, 520, 530 at time bins 542 and 544, which also correspond to 458 ns and 478 ns. Histogram 540 can have fewer time bins than were measured during the respective detection intervals, e.g., as a result of dropping time bins in the beginning or the end of the detection interval or time bins having values less than a threshold. In some implementations, about 10-30 time bins can have appreciable values, depending on the pattern for a pulse train.

As examples, the number of pulse trains emitted during a measurement to create a single histogram can be around 1-40 (e.g., 24), but can also be much higher, e.g., 50, 100, 500, or 1000. Once a measurement is completed, the counts for the histogram can be reset, and another set of pulse trains can be emitted to perform a new measurement. In various embodiments and depending on the number of detection intervals in the respective measurement cycles, measurements can be performed, e.g., every 25, 50, 100, or 500 μs. In some embodiments, measurement intervals can overlap, e.g., so that a given histogram corresponds to a particular sliding window of pulse trains. In such an example, memory can be provided for storing multiple histograms, each corresponding to a different time window. Any weights applied to the detected pulses can be the same for each histogram, or such weights could be independently controlled.

### 3. Pixel Operation

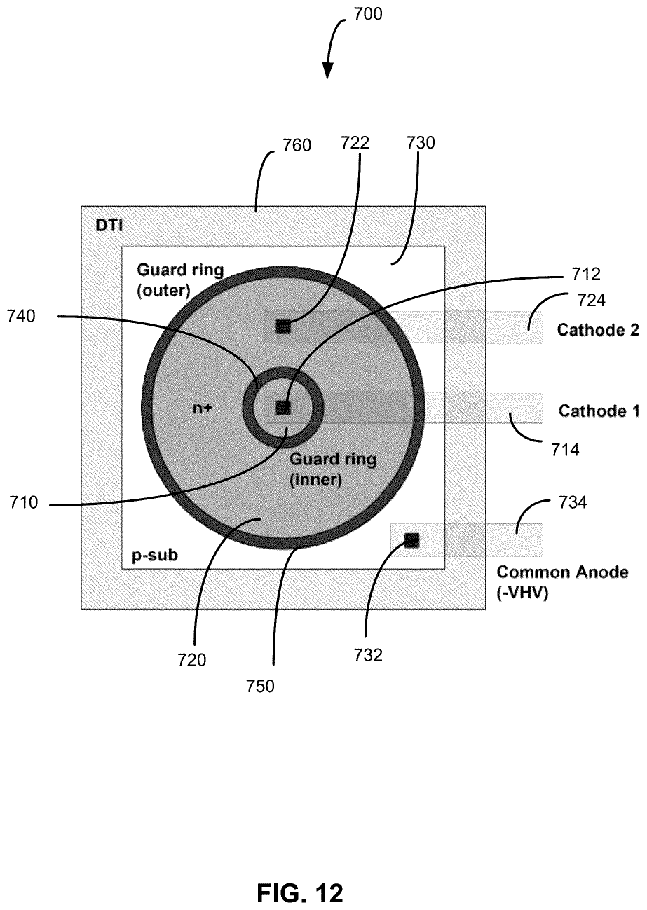

In some embodiments of the present invention, detector pixel 600, or more simply pixel 600, can include memory block 610, precharge-read-modify-write (PRMW) logic circuits 630, address generator 620, and timing control circuit 650 (all shown in FIG. 6.) Pixel 600 can include one or more photodetectors, such as SPAD devices 700 (shown in FIG. 12), as well as other circuits or components (not shown.) Pixel 600 can be used as sensor 142 (shown in FIG. 1.)

FIG. 6 illustrates an example of a pixel according to an embodiment of the present invention. Pixel 600 can include an Y×4W memory block 610. Memory block 610 can include an array of memory cells arranged in Y rows and 4W columns, where the 4W columns are arranged as four memory banks 640 or sections, each having W memory cells. As shown in FIG. 6, timing control circuit 650 can receive a pixel clock on line 652. Timing control circuit 650 can provide an address generator clock on line 654 and pre-charge, read, modify, and write signals on lines 656 to PRMW logic circuits 630. Memory block 610 can be addressed using address generator 620 that provides Y row addresses on lines 622. Pixel 600 can include four PRMW logic circuits 630 of W bits each for a total of 4W bits, corresponding to the number of bitlines 612 or columns in memory block 610. In this configuration, four bins can be stored in each row of memory block 610. In these and other embodiments of the present invention, Y can have a value of 32, 36, 40, 64, or other value, while W can have a value of 8, 10, 12, 16, or other value. Memory block 610 can be divided into two, three, five, or more than five sections with a corresponding number of PRMW logic circuits 630.

Pixels 600 can histogram events detected from one or more SPAD devices 700 (shown in FIG. 12) following an emitted pulse from emitter array 230 (shown in FIG. 2.) That is, the number of detected events from one or more SPAD devices 700 can be time-sliced into bins and accumulated in memory block 610. For example, the number of detected SPAD events from four preceding bins can be stored in a temporary memory in the PRMW logic circuits 630 or other related circuit. Pixel 600 can perform a series of tasks, wherein during a first clock cycle, the PRMW logic circuits 630, under the control of timing control circuit 650, can perform a precharge task, where bitlines 612 for memory block 610 can be precharged. During a second clock cycle, the memory cells in the addressed row can be read by PRMW logic circuits 630. Bin counts stored in the addressed row can be modified by the PRMW logic circuits 630 by adding values from the temporary memory to the read value. The PRMW logic circuits 630 can then perform a write task to write the modified bin counts back to the memory cells for the four bins in the addressed row in memory block 610. Further details of pixel 600 are described, for example, in U.S. Patent Application Publication No. 63/216,580, entitled “Highly Parallel Large Memory Histogramming Pixel for Direct Time of Flight Lidar,” the disclosure of which is incorporated by reference herein in its entirety for all purposes.

### 4. Using Ambient Light to Set SPAD Device Sensitivity

The SPAD devices in a detector array can receive ambient light, such as solar radiation or other light source in the environment. Under some conditions, this ambient light can provide enough photons to saturate SPAD devices in a first portion of a detector array. That is, SPAD devices in the first portion of the array can become saturated due to ambient light such that their corresponding bin counts can remain at or near a maximum level. When this saturation occurs, reflected light from the emitter elements can be difficult to detect and image information can be lost. To avoid saturation by ambient light, an f-stop of an aperture that allows light to reach the detector array can be increased. This increase in f-stop can block some of the ambient light to the SPAD devices in the first portion of the detector array and can help to reduce some SPAD device saturation. Unfortunately, the increase in f-stop can also block light from reaching SPAD devices in other portions of the detector array, thereby causing a loss of detail in corresponding portions of the resulting lidar image.

Accordingly, these and other embodiments of the present invention can provide various circuits, methods, and apparatus for adjusting a sensitivity of one or more SPAD devices based on ambient light. Where high ambient light levels exist for a first portion of a scene, the sensitivity of the corresponding SPAD devices can be set to a low-sensitivity level. This low sensitivity, along with wavelength filtering, can help to avoid SPAD device saturation and allow image recovery in the first portion of the scene. Where low ambient light levels exist for a second portion of a scene, the sensitivity of the corresponding SPAD devices can be set to a high-sensitivity level to bring out poorly lit details. An example is shown in the following figures.

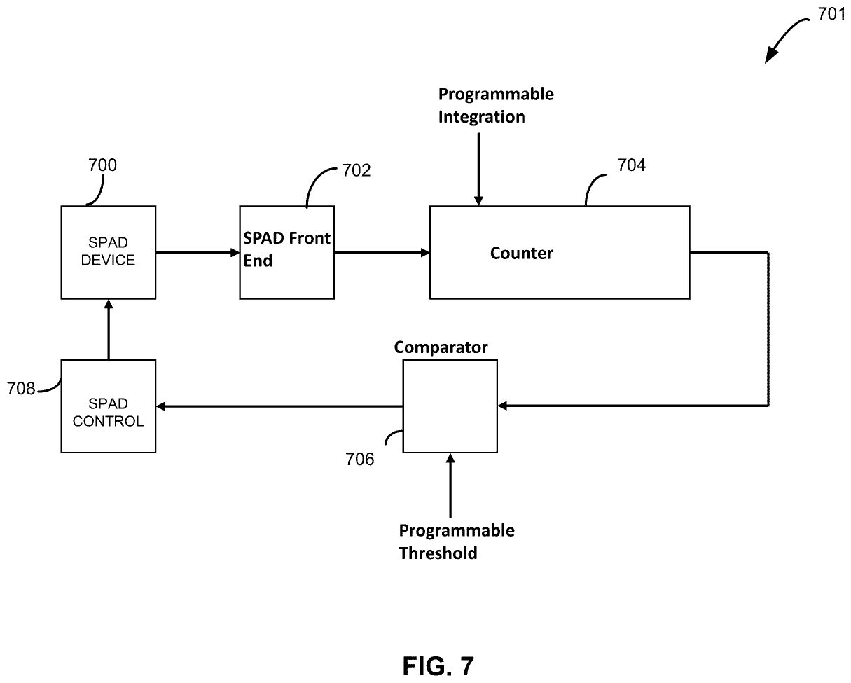

FIG. 7 illustrates a circuit for setting a sensitivity of one or more SPAD devices using ambient light conditions according to an embodiment of the present invention. SPAD sensitivity circuit 701 can determine a photon count caused by ambient light. A comparison can be made to a threshold count that can be fixed or programmable. If an excess photon count is observed, one or more SPAD devices can be put or kept in a low-sensitivity mode to avoid SPAD device saturation. If a low photon count is observed, one or more SPAD devices can be put or kept in a high-sensitivity mode to improve a resulting image.

SPAD sensitivity circuit 701 can adjust a sensitivity for one or more SPAD devices 700. For example, SPAD sensitivity circuit 701 can adjust a sensitivity for one SPAD device 700. Alternatively, SPAD sensitivity circuit 701 can adjust a sensitivity for each of SPAD device 700 in a pixel 600. Alternatively, SPAD sensitivity circuit 701 can adjust a sensitivity for the SPAD devices 700 in a group of pixels. Alternatively, SPAD sensitivity circuit 701 can adjust the sensitivity for each of the SPAD devices 700 in a row of pixels. For simplicity, each of these SPAD devices 700 or groups of SPAD devices 700 are shown in this figure as SPAD device 700.

SPAD front end 702 can communicate with SPAD device 700 and provide an output to counter 704. Counter 704 can accumulate event information for a scene provided by SPAD front end 702 for a number of cycles, where the number of cycles can be determined by the programmable integration signal received by counter 704.

Comparator 706 can compare the count accumulated by counter 704 to a programmable threshold value. This comparison can be done for each SPAD device 700, for each SPAD device 700 in a pixel 600, for each SPAD device 700 in a group of pixels 600, for each SPAD device 700 in a row of pixels 600, or the SPAD devices 700 for another set of some or all of the pixels 600 in a system.

The output of comparator 706 can be received by SPAD control circuit 708. SPAD control circuit 708 can use the comparison information provided by comparator 706 to adjust a sensitivity of one or more SPAD devices 700, for example the SPAD devices 700 in a pixel 600, the SPAD devices 700 in a group of pixels 600, SPAD devices 700 for a row of pixels 600, or for the SPAD devices 700 in another set of some or all of the pixels 600 in the system. Representative methods of operating this circuit are shown in the following figures.

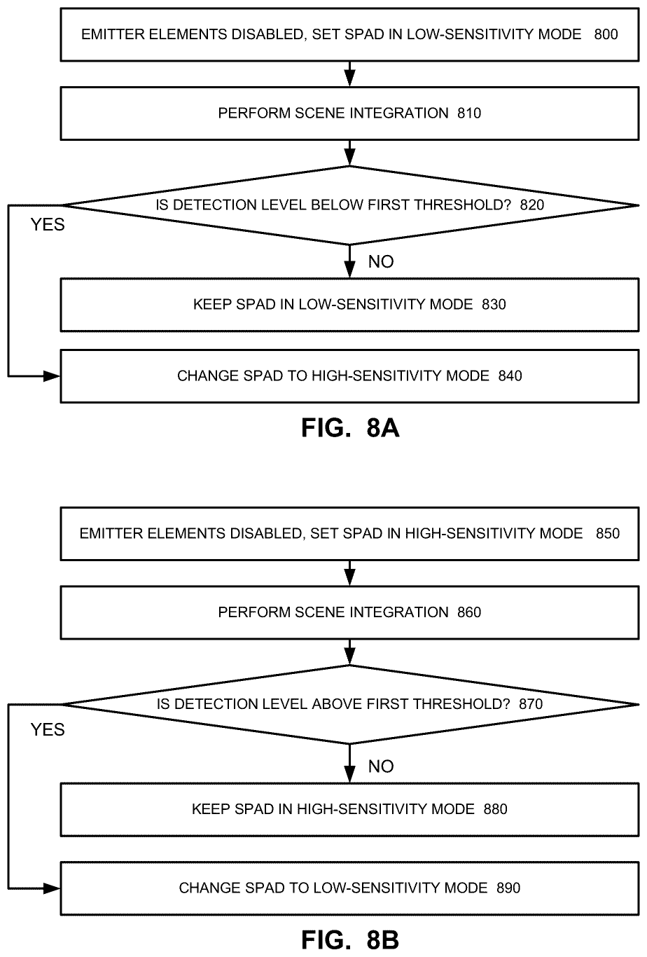

FIGS. 8A and 8B are flowcharts for setting a sensitivity of one or more SPAD devices using ambient light according to an embodiment of the present invention. In act 800 of FIG. 8A, the emitter elements can be disabled and some or all the SPAD devices can be set in the low-sensitivity mode. In act 810, a scene integration can be performed. This integration can capture ambient light information for the scene. In act 820, it can be determined whether a detected level of ambient-light induced events is below a first threshold. This determination can be made for each SPAD device, for the SPAD devices in a pixel, for the SPAD devices in a group of pixels, for the SPAD devices in a row of pixels, or for the SPAD devices in another set of some or all of the pixels in a system. Each SPAD device or group of SPAD devices where little or no signal is received and the accumulated counts are below the first threshold can be changed to a high-sensitivity mode in act 840. Each SPAD device or group of SPAD devices where a detected level of ambient-light induced events is above the first threshold can be kept in the low-sensitivity mode in act 830.

In act 850 of FIG. 8B, the emitter elements can be disabled and some or all the SPAD devices 700 can be set in the high-sensitivity mode. In act 860, a scene integration can be performed. This integration can capture ambient light information for the scene. In act 870, it can be determined whether a detected level of ambient-light induced events is above a first threshold. This determination can be made for each SPAD device, for the SPAD devices in a pixel, for the SPAD devices in a group of pixels, for the SPAD devices in a row of pixels, or for the SPAD devices in another set of some or all of the pixels in a system. Each SPAD device or group of SPAD devices where the accumulated counts are above the first threshold can be changed to a low-sensitivity mode in act 880. Each SPAD device or group of SPAD devices where a detected level of ambient-light induced events is below the first threshold can be kept in the high-sensitivity mode in act 880.

### 5. Using Partial Time-of-Flight Data to Set SPAD Device Sensitivity

The amount of light from emitter elements that is reflected to the detector array can vary greatly. For example, a first object at a distance might reflect minimal light, thus making a low f-stop desirable. Other objects can be closer or have a higher reflectivity. Under these conditions, particularly when an aperture for the detector array is set with a low f-stop, high-intensity reflected light can be received by SPAD devices in a first portion of a detector array. Such an amount of light can again saturate SPAD devices in the first portion of detector array. When this occurs, information regarding a reflectivity of an object can be lost. For example, it might be known that an object has at least a certain level of reflectivity, though the actual reflectivity of the object might not be quantifiable. As before, an f-stop of an aperture that allows light to reach the detector array can be increased. This increase in f-stop can block some of the reflected light from reaching SPAD devices in the first portion of the detector array and can help to reduce some SPAD device saturation. Unfortunately, the increase in f-stop can also block light from reaching SPAD devices in other portions of the detector array, again causing a loss of detail in corresponding portions of the resulting lidar image.

Accordingly, these and other embodiments of the present invention can use partial time-of-flight data in determining a sensitivity setting for one or more SPAD devices. For example, time-of-flight data for a limited number of emitter pulses can be accumulated. Where a large number of photon counts are detected for a portion of a scene, the sensitivity of the corresponding SPAD devices can be set to a low-sensitivity level. Where a low number of photon counts are detected for portion of a scene, sensitivity of the corresponding SPAD devices can be set to a high-sensitivity level. An example is shown in the following figures.

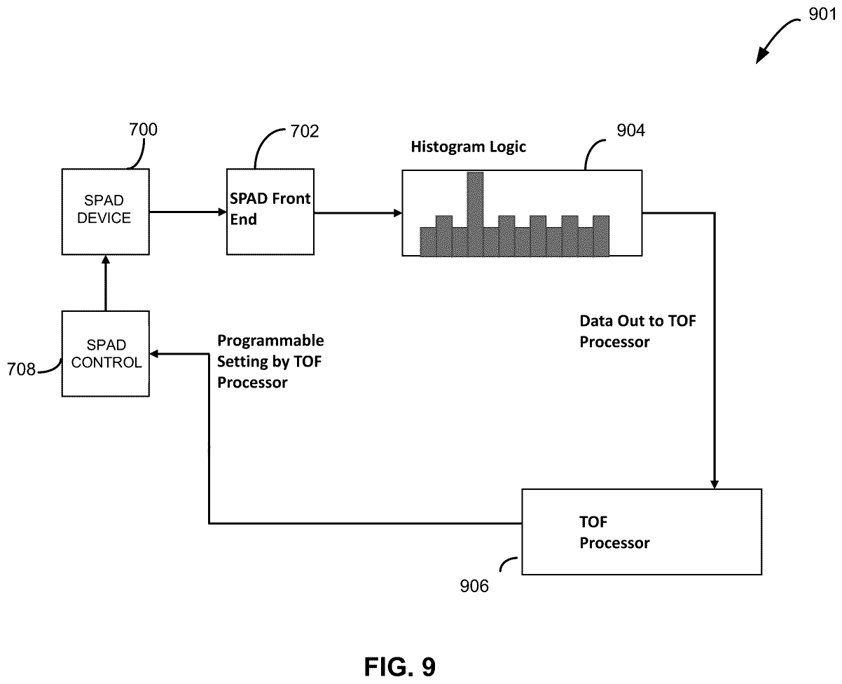

FIG. 9 illustrates a circuit for setting a sensitivity of one or more SPAD devices using partial time-of-flight data according to an embodiment of the present invention. SPAD sensitivity circuit 901 can adjust a sensitivity for one or more SPAD devices 700. For example, SPAD sensitivity circuit 901 can adjust a sensitivity for one SPAD device 700. Alternatively, SPAD sensitivity circuit 901 can adjust a sensitivity for each of SPAD device 700 in a pixel 600. Alternatively, SPAD sensitivity circuit 901 can adjust a sensitivity for the SPAD devices 700 in a group of pixels. Alternatively, SPAD sensitivity circuit 901 can adjust the sensitivity for each of the SPAD devices 700 in a row of pixels. For simplicity, each of these SPAD devices 700 or groups of SPAD devices 700 are shown in this figure as SPAD device 700.

SPAD front end 702 can communicate with SPAD device 700 and provided output to histogram logic 904. Histogram logic 904 can accumulate event or photon count information provided by SPAD front end 702 for a number of cycles.

Time-of-flight processor 906 can analyze the histogram collected by histogram logic 904 and determine a sensitivity setting for each SPAD device 700. This determination can be done for each SPAD device 700, for each SPAD device 700 in a pixel 600, for each SPAD device 700 in a group of pixels 600, for each SPAD device 700 in a row of pixels 600, or for the SPAD devices 700 for another set of some or all of the pixels 600 in a system.

The output of time-of flight processor 906 can be received by SPAD control circuit 708. SPAD control circuit 708 can use the information provided by time-of flight processor 906 to set a sensitivity of one or more SPAD devices 700, for example the SPAD devices 700 in a pixel 600, the SPAD devices 700 in a group of pixels 600, the SPAD devices 700 in a row of pixels 600, or for the SPAD devices 700 in another set of some or all of the pixels 600 in the system. Representative methods of operating this circuit are shown in the following figures.

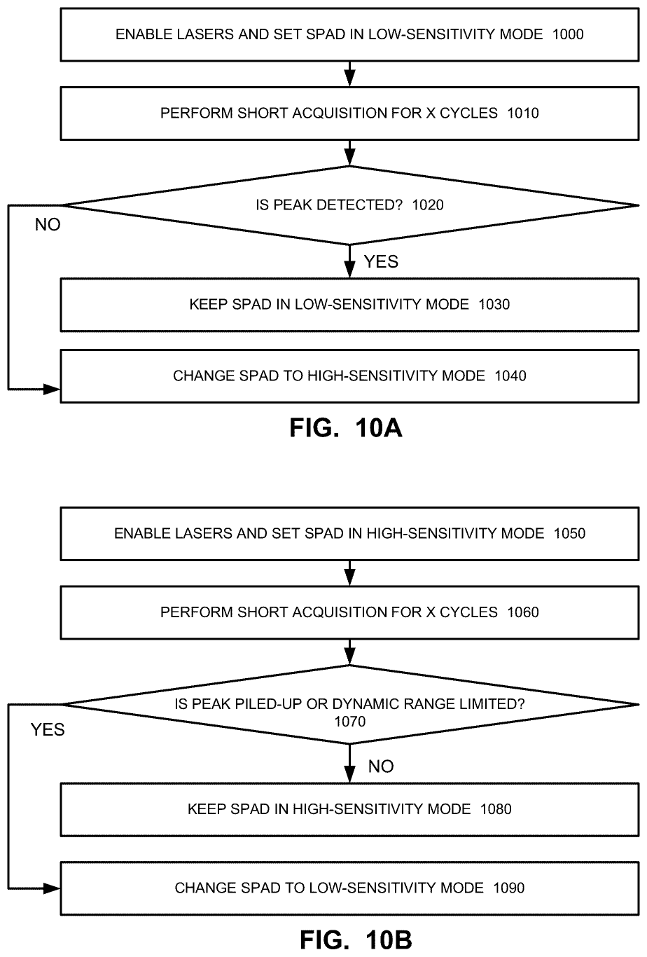

FIGS. 10A and 10B are flowcharts for setting a sensitivity of one or more SPAD devices using partial time-of-flight data according to an embodiment of the present invention. In act 1000 of FIG. 10A, the emitters can be enabled and all the SPAD devices in a system can be set in the low-sensitivity mode. In act 1010, a short acquisition for a limited number of cycles can be performed. For example, a portion, such as 10 percent, of the emitter pulses for a scene can be sent. This limited number of pulses can provide an indication of whether one or more SPAD devices are being saturated. In act 1020, it can be determined whether a peak in the count of detected events is detected. This determination can be made for each SPAD device, for the SPAD devices in a pixel, for the SPAD devices in a group of pixels, for the SPAD devices in a row of pixels, or for the SPAD devices in another set of some or all of the pixels in the system. Each SPAD device or group of SPAD devices where little or no signal is received (that is, a peak is not detected) can be changed to a high-sensitivity mode in act 1040. Each SPAD device or group of SPAD devices where a peak is detected can be kept in the low-sensitivity mode in act 1030.

In act 1050 of FIG. 10B, the emitters can be enabled and all the SPAD devices in a system can be set in the high-sensitivity mode. In act 1060, a short acquisition for a limited number of cycles can be performed. For example, a portion, such as 10 percent, of the emitter pulses for a scene can be sent. This limited number of pulses can provide an indication of whether one or more SPAD devices are being saturated. In act 1070, it can be determined whether the time-of-flight data is piled-up or dynamic range limited. This determination can be made for each SPAD device, for the SPAD devices in a pixel, for the SPAD devices in a group of pixels, for the SPAD devices in a row of pixels, or for the SPAD devices in another set of some or all of the pixels in the system. Each SPAD device or group of SPAD devices where no pile-up or dynamic range limitations are detected can be kept in the high-sensitivity mode in act 1080. Each SPAD device or group of SPAD devices where pile-up or dynamic range limitations are detected can be changed to the low-sensitivity mode in act 1090.

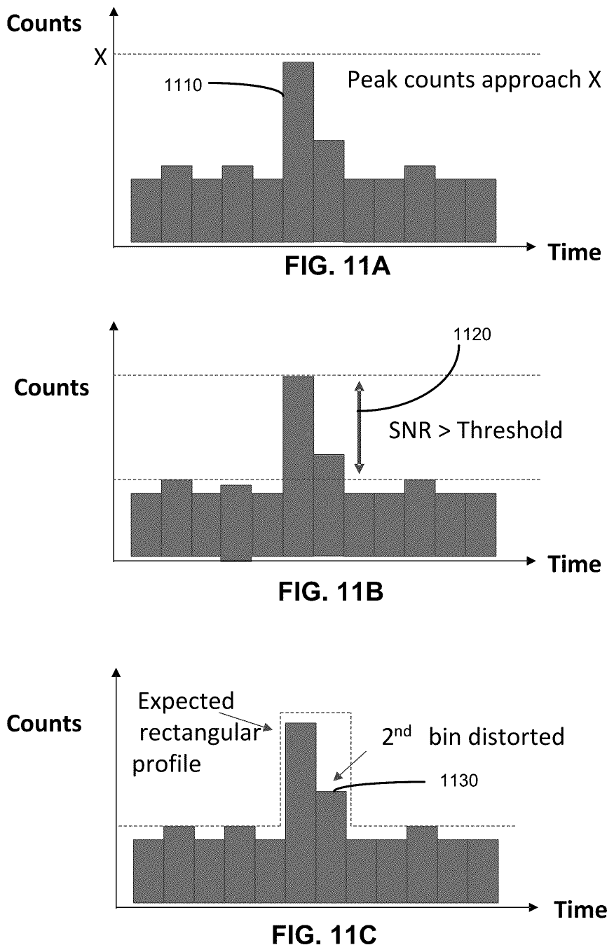

FIGS. 11A through 11C illustrate histogram data that can be used for setting a sensitivity of one or more SPAD devices using partial time-of-flight data according to an embodiment of the present invention. In FIG. 11A, it can be determined that an amplitude of counts of detected events is at or approaching a maximum value, shown here as X. When this occurs, a sensitivity of one or more corresponding SPAD devices can be adjusted to have a reduced sensitivity to avoid saturation. In FIG. 11B, it can be determined that a signal-to-noise ratio is excessive. Accordingly, a sensitivity of one or more corresponding SPAD devices can be adjusted to have a reduced sensitivity in order to avoid saturation. In FIG. 11C, it can be determined that a time-of-flight or return profile does not meet expectations. This can indicate that a time-of-flight pulse is piled-up. As a result, a sensitivity of one or more corresponding SPAD devices can be adjusted to have a reduced sensitivity.

These and other embodiments of the present invention can provide various types of SPAD devices having a variable sensitivity. Examples are shown in the following figures.

### 6. SPAD Device Having Variable Sensitivity

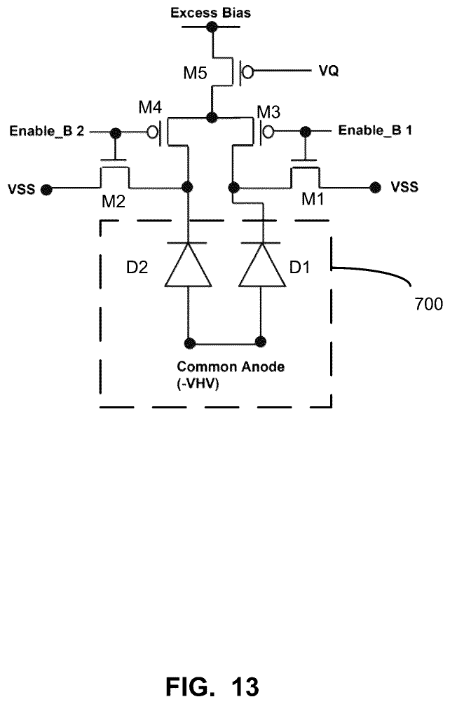

FIG. 12 illustrates a top view of a SPAD device structure according to an embodiment of the present invention. SPAD device 700 can include a first cathode region 710 and a second cathode region 720. The first cathode region 710 and the second cathode region 720 can be formed in a common anode region or collector 730. The first cathode region 710 and common anode region or collector 730 can form a first diode D1. The second cathode region 720 and the common anode or collector 730 can form a second diode D2 (D1 and D2 shown in FIG. 13.) The common anode region or collector 730 can be formed as an epitaxial layer having a first dopant. The first dopant can be a p-type or an n-type dopant. The first cathode region 710 and the second cathode region 720 can be formed as implanted or diffused regions of a second dopant in common anode region or collector 730. The second dopant can be an n-type or a p-type dopant.

In a low-sensitivity setting, the voltage at first cathode region 710 can be different than a voltage at second cathode region 720. This can cause a monotonic potential gradient from first cathode region 710 to second cathode region 720, which can create a conduction path. Accordingly, to prevent current from flowing from first cathode region 710 to second cathode region 720, either the monotonic potential gradient or the conduction path can be disrupted. For example, the monotonic potential gradient can be disrupted by the inclusion of an implanted or diffused region of the first dopant or the second dopant forming a first guard ring 740 between first cathode region 710 and second cathode region 720. That is, a p-type implanted or diffused region can be used to form first guard ring 740 between first cathode region 710 and second cathode region 720. A deeper, p-well implant or diffusion region forming first guard ring 740 can be included. Various implants having different concentrations of p-type or n-type dopant can be used. Alternatively, the conduction path from first cathode region 710 and second cathode region 720 can be disrupted. For example, a shallow isolation trench can be formed between first cathode region 710 and second cathode region 720. The shallow isolation trench can be formed using a deep-reactive ion etch or other process. A layer of oxide, such as silicon dioxide, can be formed over the edges and bottom of the resulting trench. The trench can be filled with an oxide, such as silicon dioxide. These techniques can also be combined. For example, one or more diffused or implanted regions can be formed along sides of or below the resulting trench.

A second guard ring 750 can be formed around the first cathode region 710 and the second cathode region 720. Second guard ring 750 can be formed as implanted or diffused regions having the first dopant or the second dopant. For example, second guard ring 750 can comprise a lightly doped p-type region. Alternatively, second guard ring 750 can comprise a lightly doped n-type region. Alternatively, second guard ring 750 can be formed of a shallow trench (not shown.) This shallow trench can be at least partially filled with oxide layer or silicon dioxide.

A deep trench isolation channel 760 can be formed at an outer boundary of SPAD device 700. Instead of a deep trench isolation channel 760, one or more n-type diffused regions can be used to define an outer perimeter of SPAD device 1100.

First cathode region 710 can be contacted using contact 712 and connected to the CATHODE_1 signal on traces 714. Second cathode region 720 can be contacted using contact 722 and connected to the CATHODE_2 signal on trace 724. Common anode or collector 730 can be contacted using contact 732 and connected to the common anode trace 734. Alternatively, common anode or collector 730 can be contacts at a back side of SPAD device 700.

In this example, first cathode region 710 can have a disk-shaped surface profile. Second cathode region 720 can have an annular-shaped surface profile formed around first cathode region 710. In these and other embodiments of the present invention, other shapes, such as squares, rectangles, ellipsoid's, and others can be utilized.

The sensitivity of SPAD device 700 can be varied. For example, the first diode D1 formed by first cathode region 710 and collector 730 and the second diode D2 formed by second cathode region 720 and collector 730 can both be biased above their breakdown voltage. This biasing configuration can provide a maximum sensitivity for SPAD device 700. To reduce the sensitivity of SPAD device 700, either the first diode D1 or the second diode D2 can be disabled by being biased below their breakdown voltage. In this configuration, the biasing voltages can be varied in order to further tune or adjust the sensitivity of SPAD device 700. A circuit that can be used to disable either or both of the first diode D1 and the second diode D2 is shown in the following figure.

FIG. 13 illustrates a circuit for tuning a sensitivity of a SPAD device according to an embodiment of the present invention. In this example, first diode D1 and second diode D2 can share a common anode. Again, as shown in FIG. 12, first diode D1 can be formed by first cathode region 710 and common anode or collector 730, while second diode D2 can be formed by second cathode region 720 and common anode or collector 730. The common anode region or collector 730 can be connected to a negative voltage, shown here as −VHV.

The cathode of first diode D1 can be grounded to VSS through transistor M1 when the ENABLE_B1 signal at the gate of M1 is high. This can disable first diode D1. When ENABLE_B1 is high, transistor M3 can be off, thereby disconnecting first the diode D1 from transistor M4 and transistor M5. When ENABLE_B1 is low, transistor M1 can disconnect the cathode of first diode D1 from VSS and transistor M3 can be on. When VQ is low, transistor M5 can also be on, thereby connecting the anode of first diode D1 to the supply voltage EXCESS_BIAS, which can reverse bias the first diode D1 above its threshold voltage.

Similarly, the cathode of second diode D2 can be grounded to VSS through transistor M2 when the ENABLE_B2 signal at the gate of M2 is high. This can disable second diode D2. When ENABLE_B2 is high, transistor M4 can be off, thereby disconnecting the second diode D2 from transistor M3 and transistor M5. When ENABLE_B2 is low, transistor M2 can disconnect the cathode of second diode D2 from VSS and transistor M4 can be on. When VQ is low, transistor M5 can also be on, thereby connecting the anode of second diode D2 to the supply voltage EXCESS_BIAS, which can reverse bias the second diode D2 above its threshold voltage.

Accordingly, when both ENABLE_B1 and ENABLE_B2 are low, transistors M3 and transistor M3 can be on, and the cathodes of first diode D1 and second diode D2 can be connected to each other. When the VQ signal at the gates of M5 is low, the cathodes of first diode D1 and second diode D2 can be connected to the SPAD positive biasing voltage, shown here as EXCESS_BIAS. This can enable both first diode D1 and second diode D2.

In this biasing configuration, SPAD device 700 can have its highest sensitivity since both the first diode D1 and the second diode D2 are biased above their breakdown voltages. Specifically, the first diode D1 and the second diode D2 can be reversed biased with a voltage having a magnitude equal to the sum of the magnitudes of the EXCESS_BIAS supply and the negative voltage −VHV. The sensitivity of SPAD device 700 can be reduced by a high input on either ENABLE_B1 or ENABLE_B2. A high at ENABLE_B1 can reduce the reverse bias voltage across first diode D1 by grounding its cathode. In this configuration, first diode D1 can have a magnitude equal to the magnitude of the −VHV supply, which can be below the breakdown voltage for first diode D1. A high at ENABLE_B2 can reduce the reverse bias voltage across second diode D2 by grounding its cathode. In this configuration, second diode D2 can have a magnitude equal to the magnitude of the −VHV supply, which can be below the breakdown voltage for second diode D2. By adjusting the relative sizes of the cathodes of the first diode D1 and the second diode D2 (for example, the first cathode region 710 and the second cathode region 720 as shown in FIG. 12), the variation in sensitivity of SPAD device 700 can be changed. Further tuning can be achieved by varying the EXCESS_BIAS voltage and the −VHV voltage. A passive quench can be initiated by a high voltage on line VQ, which can turn off transistor M5. An example illustrating the operation of SPAD device 700 when both diodes are reversed biased above their breakdown voltage is shown in the following figure.

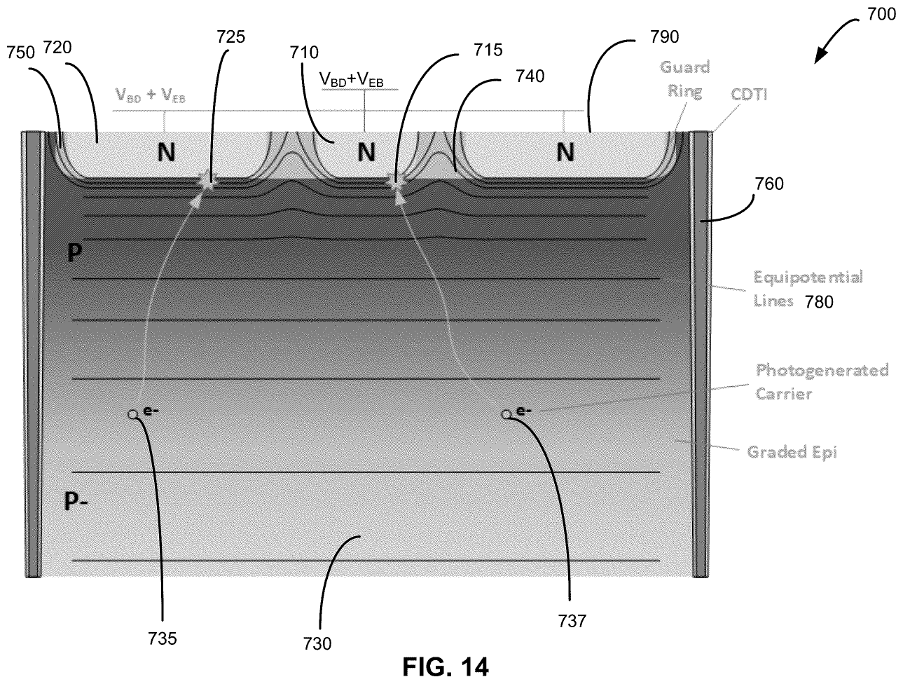

FIG. 14 illustrates a cross-section of a SPAD device according to an embodiment of the present invention. In this example, common anode or collector 730 can be an epitaxial p-type region, where the dopants are graded to have higher concentrations near the top surface 790 of SPAD device 700. Common anode or collector 730 can be an epitaxial layer that is grown on a handle wafer or other substrate (not shown.) The handle wafer or other substrate can be removed, for example back-lapping, etching, or other process. In these and other embodiments of present invention, common anode or collector 730 can have various concentrations and dopants.

First cathode region 710 can be implanted or diffused in the epitaxial layer that forms collector 730. First cathode region 710 can be highly doped n-type region. Second cathode region 720 can be implanted or diffused in the epitaxial layer that forms collector 730. Second cathode region 720 can be highly doped n-type region. First cathode region 710 and second cathode region 720 can be formed in the same processing step.

A first guard ring 740 can separate first cathode region 710 from second cathode region 720. First guard ring 740 can be formed as implanted or diffused regions having the first dopant or the second dopant. For example, first guard ring 740 can comprise a lightly doped p-type region. Alternatively, first guard ring 740 can comprise a lightly doped n-type region. Alternatively, first guard ring 740 can be formed of as shallow trench isolation (not shown.) This shallow trench can be at least partially filled with an oxide layer or silicon dioxide. Alternatively, first guard ring 740 can be formed as a shallow trench isolation with a diffused or implanted region along sides or under the trench.

A second guard ring 750 can be formed around the first cathode region 710 and the second cathode region 720. Second guard ring 750 can be formed as implanted or diffused regions having the first dopant or the second dopant. For example, second guard ring 750 can comprise a lightly doped p-type region. Alternatively, second guard ring 750 can comprise a lightly doped n-type region. Alternatively, second guard ring 750 can be formed of a shallow trench (not shown.) This shallow trench can be at least partially filled with oxide layer or silicon dioxide.

A deep trench isolation channel 760 can be formed at an outer boundary of SPAD device 700. Instead of a deep trench isolation channel 760, one or more n-type diffused regions can be used to define an outer perimeter of SPAD device 1100.

In this example, the first diode D1, which can include first cathode region 710 and common anode or collector 730, and the second diode D2, which can include second cathode region 720 and common anode or collector 730, can both be biased above their breakdown voltage. In this configuration, SPAD device 700 can be at its highest sensitivity. Specifically, both the first diode D1 and the second diode D2 can be biased to their breakdown voltage plus an excess potential. Photons (not shown) can generate photogenerated carriers or electrons 735 and 737. Photogenerated carriers 735 and 737 can be electrons. These electrons can be attracted to the positive voltages applied at first cathode region 710 and second cathode region 720. For example, electron 735 can be attracted to second cathode region 720. Electron 735 can reach a portion of the multiplication region of second cathode region 720, illustrated here as location 725. Similarly, electron 737 can be attracted to first cathode region 710. Electron 737 can reach a portion of the multiplication region of first cathode region 710, illustrated here as location 715. As a result, electron 735 can start an avalanche in the second diode D2, while electron 737 can start an avalanche in the first diode D1.

In this biasing configuration, the electric field in collector 730 below first cathode region 710 and below second cathode region 720 can be fairly uniform, as can be seen by the parallel equipotential lines 780. First guard ring 740 and second guard ring 750 can reduce the electric field at the periphery of first cathode region 710 and second cathode region 720. This can be seen by the more widely spaced equipotential lines 780 at the edges of first cathode region 710 and second cathode region 720. In this way, first guard ring 740 and second guard ring 750 can help to reduce edge breakdown of SPAD device 700 and provide a more predictable performance. As a result of these electric fields, a photogenerated carrier in collector 730 can find either first cathode region 710 or second cathode region 720 with a likelihood based on their comparative areas. In this example, since second cathode region 720 is much larger than first cathode region 710, a large percentage of photogenerated carriers in collector 730 can reach the multiplication region of second cathode region 720.

The sensitivity of SPAD device 700 can be adjusted by disabling one of the first diode D1 and second diode D2. The sensitivity can be further tuned by varying the bias voltages applied to the first diode D1 and second diode D2. An example is shown in the following figure.

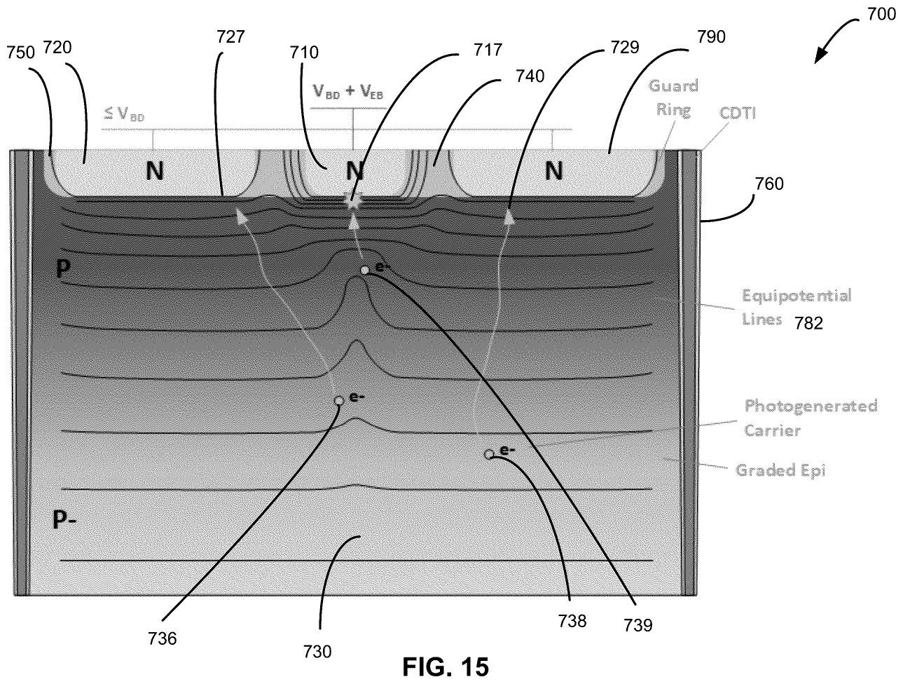

FIG. 15 is another cross-section view of a SPAD device according to an embodiment of the present invention. In this example, first diode D1, which can be formed by first cathode region 710 and common anode or collector 730, can be biased above its breakdown voltage. Second diode D2, which can be formed by second cathode region 720 and common anode or collector 730, can be biased below its breakdown voltage. In this example, second cathode region 720 of second diode D2 can be grounded, thereby reducing the reverse bias voltage and disabling diode D2. Photons (not shown) can generate photogenerated carriers or electrons 736, 738, and 739. In this example, electron 736 can be attracted to the positive voltage provided at the second cathode region 720. Similarly, electron 738 can be attracted to the second cathode region 720. In this way, second cathode region 720 can form a drain for electrons 736 and 738. Since the second diode formed by second cathode region 720 and collector 730 is biased below its breakdown region, the avalanche process might not begin in SPAD device 700 as a result of the movement of electrons 736 and 738.

Conversely, electron 739 can be attracted to the positive voltage applied at first cathode region 710. Since the first diode D1, including first cathode region 710 and common anode or collector 730, is biased above its breakdown voltage, that is it is enabled, electron 739 might reach the multiplication region of diode D1, shown here as location 717. Accordingly, 739 might cause an avalanche in SPAD device 700.

In this configuration, since second cathode region 720 is grounded and can form a drain for carriers, a reduced percentage or minority of carrier photogenerated in collector 730 are likely to start an avalanche in SPAD device 700. Accordingly, SPAD device 700 can be less sensitive when the second diode D2 is disabled and the first diode D1 is enabled. The same can be true to a different degree when the first diode D1 is disabled and the second diode D2 is enabled.

In this example, when second diode D2 is disabled and first diode D1 is enabled, second cathode region 720 can be grounded while first cathode region 710 can be biased above ground. This can cause a monotonic potential gradient from first cathode region 710 to second cathode region 720, which can create a conduction path. Accordingly, to prevent current from flowing from first cathode region 710 to second cathode region 720, either the monotonic potential gradient or the conduction path can be disrupted. For example, the monotonic potential gradient can be disrupted by the inclusion of an implanted or diffused p-type region forming a first guard ring 740 between first cathode region 710 and second cathode region 720. A deeper, p-well implant or diffusion region forming first guard ring 740 can be included. Various implants having different concentrations of p-type or n-type dopant can be used. Alternatively, the conduction path from first cathode region 710 and second cathode region 720 can be disrupted. For example, a shallow isolation trench can be formed between first cathode region 710 and second cathode region 720. The shallow isolation trench can be formed using a deep-reactive ion etch or other process. A layer of oxide, such as silicon dioxide, can be formed over the edges and bottom of the resulting trench. The trench can be filled with an oxide, such as silicon dioxide. These techniques can also be combined. For example, one or more diffused or implanted regions can be formed along sides of or below the resulting trench.

The sensitivity of SPAD device 700 can be varied by disabling either or both the first diode D1 or the second diode D2 by grounding either first cathode region 710 or second cathode region 720. In the example of FIG. 10, the second cathode region 720 can be grounded to disable second diode D2 and lower the sensitivity of SPAD device 700. This sensitivity can be further adjusted by varying the bias voltages applied to first diode D1 and second diode D2. As shown in FIG. 13, the common anode or collector 730 of first diode D1 and second diode D2 can receive the power supply −VHV. When second diode D2 is disabled, second cathode region 720 can be connected to VSS or ground, and the reverse bias voltage across second diode D2 has a magnitude of VHV. When first diode D1 is enabled, first cathode region 710 is connected to the power supply EXCESS_BIAS, and the reverse bias voltage across first diode D1 has a magnitude equal to the magnitude of EXCESS_BIAS plus the magnitude of VHV. The magnitude of VHV can be less than the magnitude of the breakdown voltage of the second diode D2. The magnitude of EXCESS_BIAS plus the magnitude of VHV can be greater than the magnitude of the breakdown voltage of the first diode D1.

In this configuration, when the magnitudes of the reverse bias voltages across the first diode D1 and the second diode D2 are close, the strength of the resulting electric field in collector 730 can be somewhat uniform as a function of depth in collector 730. (As an example, when first diode D1 and second diode D2 have the same biasing, equipotential lines 780 in collector 730 as shown in FIG. 14 can be fairly uniform or linear at a given depth.) This uniformity can indicate that each photogenerated carrier in collector 730 can find a cathode region that is largely determined by the cathode regions area. When the reverse bias voltage across the disabled second diode D2 is much less than the reverse bias voltage across the enable first diode D1, the electric field under the first cathode region 710 can be higher than the electric field under the second cathode region 720. This can be seen by the shape of equipotential lines 782. This difference in potential can tend to increase a likelihood that a photogenerated carrier in collector 730 can reach the multiplication region of the first cathode region 710.

### 7. Fine-Tuning of SPAD Device in Low-Sensitivity Mode

Accordingly, as the reverse bias voltage across the disabled second diode D2 increases and becomes closer in magnitude to the reverse bias voltage across the enabled first diode D1, the photogenerated carriers can be steered towards second cathode region 720. Since the second diode D2 is disabled, steering photogenerated carriers towards the second cathode region 720 can reduce the sensitivity of SPAD device 700. Accordingly, SPAD device 700 can be reduced in sensitivity by increasing the voltage across the disabled second diode D2 as compared to the enabled first diode D1. For example, increasing the magnitude of the supply voltage −VHV and decreasing the magnitude of the supply voltage EXCESS_BIAS can reduce the sensitivity of SPAD device 700. Alternately, instead of grounding second cathode region 720, second cathode region 720 can be connected to receive an input voltage where the input voltage provides further tuning of the SPAD device 700. An example is shown in the following figure.

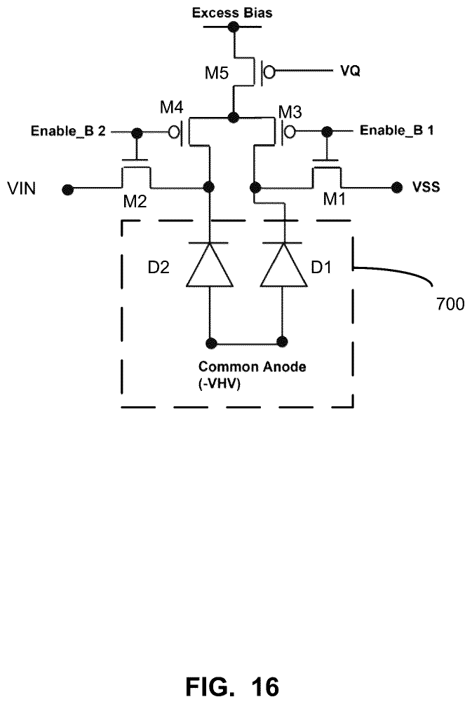

FIG. 16 illustrates a circuit for tuning a sensitivity of a SPAD device according to an embodiment of the present invention. In this example, first diode D1 and second diode D2 can share a common anode. Again, as shown in FIG. 12, first diode D1 can be formed by first cathode region 710 and common anode or collector 730, while second diode D2 can be formed by second cathode region 720 and common anode or collector 730. The common anode region or collector 730 can be connected to a negative voltage, shown here as −VHV.

The cathode of first diode D1 can be grounded to VSS through transistor M1 when the ENABLE_B1 signal at the gate of M1 is high. This can disable first diode D1. When ENABLE_B1 is high, transistor M3 can be off, thereby disconnecting first the diode D1 from transistor M4 and transistor M5. When ENABLE_B1 is low, transistor M1 can disconnect the cathode of first diode D1 from VSS and transistor M3 can be on. When VQ is low, transistor M5 can also be on, thereby connecting the anode of first diode D1 to the supply voltage EXCESS_BIAS, which can reverse bias the first diode D1 above its threshold voltage.

The cathode of second diode D2 can be connected to VIN through transistor M2 when the ENABLE_B2 signal at the gate of M2 is high. This can disable second diode D2 while changes in VIN can vary the sensitivity of first diode D1. That is, as VIN is increased, the electric field across second diode D2 can increase. This increased electric field can draw carriers (electrons) towards second cathode region 720 of second diode D2, thereby lowering a sensitivity of SPAD device 700. As VIN is decreased, the electric field across second diode D2 can decrease. This decreased electric field can draw carriers towards first cathode region 710 of first diode D1, thereby increasing a sensitivity of SPAD device 700.

When ENABLE_B2 is high, transistor M4 can be off, thereby disconnecting the second diode D2 from transistor M3 and transistor M5. When ENABLE_B2 is low, transistor M2 can disconnect the cathode of second diode D2 from VIN and transistor M4 can be on. When VQ is low, transistor M5 can also be on, thereby connecting the anode of second diode D2 to the supply voltage EXCESS_BIAS, which can reverse bias the second diode D2 above its threshold voltage.

Accordingly, when both ENABLE_B1 and ENABLE_B2 are low, transistors M3 and transistor M3 can be on, and the cathodes of first diode D1 and second diode D2 can be connected to each other. When the VQ signal at the gates of M5 is low, the cathodes of first diode D1 and second diode D2 can be connected to the SPAD positive biasing voltage, shown here as EXCESS_BIAS. This can enable both first diode D1 and second diode D2.

In this biasing configuration, SPAD device 700 can have its highest sensitivity when both the first diode D1 and the second diode D2 are biased above their breakdown voltages. Specifically, the first diode D1 and the second diode D2 can be reversed biased with a voltage having a magnitude equal to the sum of the magnitudes of the EXCESS_BIAS supply and the negative voltage −VHV. The sensitivity of SPAD device 700 can be reduced by a high input on either ENABLE_B1 or ENABLE_B2. A high at ENABLE_B1 can reduce the reverse bias voltage across first diode D1 by grounding its cathode. In this configuration, first diode D1 can have a magnitude equal to the magnitude of the −VHV supply, which can be below the breakdown voltage for first diode D1. A high at ENABLE_B2 can reduce the reverse bias voltage across second diode D2 by connecting its cathode to the input voltage VIN. In this configuration, second diode D2 can have a magnitude equal to the magnitude of the −VHV supply summed with the input voltage VIN, which can be below the breakdown voltage for second diode D2.

Accordingly, embodiments of the present invention can adjust a sensitivity of a SPAD device 700 when SPAD device is in a low-sensitivity state caused by diode D2 being disabled. For example, a magnitude of a voltage difference between the EXCESS_BIAS supply and the negative voltage −VHV can be set in order to provide a sufficient voltage above breakdown for first diode D1. The relative voltage of across second diode D2 can be varied by grounding second cathode region 720 and moving the EXCESS_BIAS supply and the negative voltage −VHV together relative to ground. Also or alternatively, the voltage VIN at the second cathode region 720 can be varied. As these voltages are varied such that the voltage at second cathode region 720 approaches the voltage at first cathode region 710, more carriers can be diverted to second cathode region 720. More carriers diverted to second cathode region 720 can reduce the chance of an avalanche in the multiplication region of first diode D1, thereby decreasing sensitivity of SPAD device 700.

Various voltages having various polarities and magnitudes can be applied to the terminals of SPAD devices in these and other embodiments of the present invention. As shown in FIG. 13, a negative voltage can be applied to the common anode or collector 730, while a positive voltage can be applied to the first cathode region 710 and the second cathode region 720 when first diode D1 and second diode D2 are enabled. Other voltages, such as ground, can be used for either supply voltage.

### 8. Applying Fine-Tuning at Low-Sensitivity While Using Ambient Light to Set SPAD Device Sensitivity

The ability to fine-tune a sensitivity of a SPAD can be used in conjunction with SPAD sensitivity circuit 701 (shown in FIG. 7.) For example, SPAD control circuit 708 can include an up-down counter (not shown) that counts up or down depending on the output of comparator 706. The value of the up-down counter can be provided to a digital-to-analog converter (not shown) that provides an input voltage VIN (shown in FIG. 16) to the cathode of disabled second diode D2 (shown in FIG. 16.) In this way, the sensitivity of SPAD device 700 (shown in FIG. 7) can be tuned until an output of counter 704 converges on the programmable threshold received by comparator 706. These and other embodiments of the present invention can provide these or other circuits that can tune SPAD device 700 to a preset or programmable sensitivity.

### 9. Applying Fine-Tuning at Low-Sensitivity While Using Partial Time-of-Flight Data to Set SPAD Device Sensitivity

The ability to fine-tune a sensitivity of a SPAD can be used in conjunction with SPAD sensitivity circuit 901 (shown in FIG. 9.) For example, a comparator (not shown) can compare a count 1110 (shown in FIG. 11A) to a preset or programmable threshold value. The output of the comparator can drive an up-down counter (not shown.) The value of the up-down counter can be provided to a digital-to-analog converter (not shown) that provides an input voltage VIN (shown in FIG. 16) to the cathode of disabled second diode D2 (shown in FIG. 16.) In this way, the sensitivity of SPAD device 700 (shown in FIG. 9) can be tuned until count 1110 converges on the programmable threshold received by the comparator.

Alternatively, the comparator can compare a signal-to-noise ratio 1120 (shown in FIG. 11B) to a preset or programmable threshold value. The output of the comparator can drive the up-down counter, an output of which can be provided to the digital-to-analog converter that provides the input voltage VIN to the cathode of disabled second diode D2. In this way, the sensitivity of SPAD device 700 can be tuned until signal-to-noise ratio 1120 converges on the programmable threshold received by the comparator. These and other embodiments of the present invention can provide these or other circuits that can tune SPAD device 700 to a preset or programmable sensitivity.

### 10. SPAD Device Manufacturing

These and other SPAD devices can be formed in various ways according to embodiments of the present invention. For example, a handle wafer (not shown) can be received. An epitaxial layer having a graded doping profile can be grown on the handle wafer. This epitaxial layer can form the common anode or collector 730. A first cathode region 710 and second cathode region 720 can be implanted or diffused into a top surface 790 of collector 730. The first cathode region 710 and second cathode region 720 can be highly doped n-type regions. First guard ring 740 and second guard ring 750 can be implanted, diffused, etched as a shallow trench isolation, or formed using a combination of these, between and around first cathode region 710 and second cathode region 720. Deep trench isolation channels 760 can be formed along an outer perimeter of SPAD device 700. The handle wafer can be removed, for example by back-lapping, etching, or other process. The individual SPAD devices can be singulated as necessary for use in a lidar system.

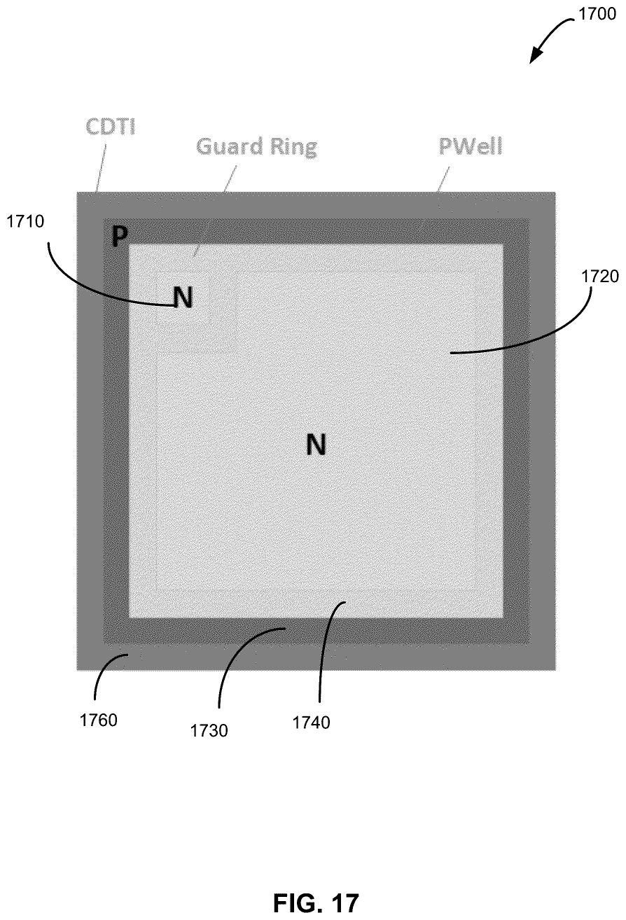

These and other SPAD devices can be formed using various materials. For example, the SPAD devices such as SPAD device 700 or SPAD device 1700 (shown in FIG. 17) can be formed primarily of silicon, germanium, gallium arsenide, or other material or combination of these or other materials. The n-type dopants can be phosphorus, arsenic, or other material or materials, while the p-type dopants can be boron or other material or materials.

### 11. Alternative SPAD Device Embodiments

FIG. 17 illustrates a surface profile of another SPAD device according to an embodiment of the present invention. In this example, SPAD device 1700 can include first cathode region 1710 and second cathode region 1720. Second cathode region 1720 can be formed as a notched square or rectangle, where first cathode region 1710 is located in the notch. A single guard ring 1740 can be formed around and between first cathode region 1710 and second cathode region 1720. A common anode or collector 1730 can be formed as an epitaxial layer below first cathode region 1710 and second cathode region 1720. Deep trench isolation channel 1760 can be formed along an outer perimeter of SPAD device 1700.

In this example, first cathode region 1710 and second cathode region 1720 can be implanted or diffused into an epitaxial layer forming common anode or collector 1730. First cathode region 1710 and second cathode region 1720 can be highly doped n-type regions.

In a low-sensitivity setting, the voltage at first cathode region 1710 can be different than a voltage at second cathode region 1720. This can cause a monotonic potential gradient from first cathode region 1710 to second cathode region 1720, which can create a conduction path. Accordingly, to prevent current from flowing from first cathode region 1710 to second cathode region 1720, either the monotonic potential gradient or the conduction path can be disrupted. For example, the monotonic potential gradient can be disrupted by the inclusion of an implanted or diffused region of the first dopant or the second dopant forming a guard ring 1740 between first cathode region 1710 and second cathode region 1720. That is, a p-type implanted or diffused region can be used to form guard ring 1740 between first cathode region 1710 and second cathode region 1720. A deeper, p-well implant or diffusion region forming guard ring 1740 can be included. Various implants having different concentrations of p-type or n-type dopant can be used. Alternatively, the conduction path from first cathode region 1710 and second cathode region 1720 can be disrupted. For example, a shallow isolation trench formed between first cathode region 1710 and second cathode region 1720. The shallow isolation trench can be formed using a deep-reactive ion etch or other process. A layer of oxide, such as silicon dioxide, can be formed over the edges and bottom of the resulting trench. The trench can be filled with an oxide such as silicon dioxide. These techniques can also be combined. For example, one or more diffused or implanted regions can be formed along sides of or below the resulting trench.

The epitaxial layer forming common anode or collector 1730 can be a graded p-type epitaxial layer, similar to the epitaxial layer used for common anode or collector 730 (shown in FIG. 15.) Instead of an implanted or diffused guard ring 1740, a shallow isolation trench can be used. Similarly, instead of a deep trench isolation channel 1760, one or more n-type diffused regions can be used to define an outer perimeter of SPAD device 1700.

While two diodes are shown in the above examples, embodiments of the present invention can include three or more than three diodes. For example, a third cathode region having an annular shape can be formed around second cathode region 720 in FIG. 12. This third cathode region along with the common anode or collector 730 can form a third diode for SPAD device 700. Similarly, a larger notch can be taken from a corner of the second cathode region in SPAD device 1700 (shown in FIG. 17) and a third cathode region can be placed in the larger notch. This third cathode region along with the common anode or collector 1730 can form a third diode for SPAD device 1700.

### 12. Multiple Lidar Units

Depending on their intended purpose or application, lidar sensors can be designed to meet different field of view (FOV) and different range requirements. For example, an automobile (e.g., a passenger car) outfitted with lidar for autonomous driving might be outfitted with multiple separate lidar sensors including a forward-facing long range lidar sensor, a rear-facing short-range lidar sensor and one or more short-range lidar sensors along each side of the car.

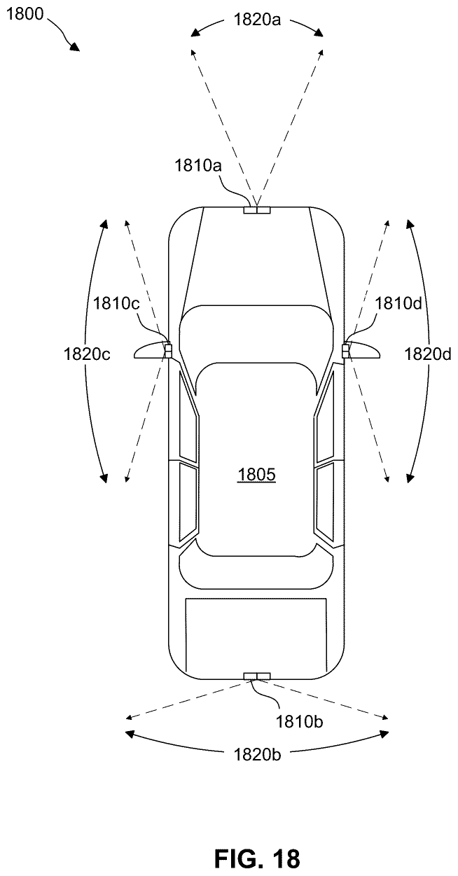

FIG. 18 is a simplified illustration of an automobile 1800 in which four solid-state flash lidar sensors 1810a-d are included at different locations along the automobile. The number of lidar sensors, the placement of the lidar sensors, and the fields of view of each individual lidar sensors can be chosen to obtain a majority of, if not the entirety of, a 360-degree field of view of the environment surrounding the vehicle some portions of which can be optimized for different ranges. For example, lidar sensor 1810a, which is shown in FIG. 18 as being positioned along the front bumper of automobile 1800, can be a long-range (200 meter), narrow field-of-view unit, while lidar sensors 1810b, positioned along the rear bumper, and lidar systems 1810c, 1810d, positioned at the side mirrors, are short-range (50 meter), wide field-of-view systems.

Despite being designed for different ranges and different fields of view, each of the lidar sensors 1810a-1910d can be a lidar system according to embodiments disclosed herein. Indeed, in some embodiments, the only difference between each of the lidar sensors 1810a-1910d is the properties of the diffuser (e.g., diffuser 136). For example, in long range, narrow field-of-view lidar sensor 1810a, the diffuser 136 is engineered to concentrate the light emitted by the emitter array of the lidar system over a relatively narrow range enabling the long-distance operation of the sensor. In the short-range, wide field-of-view lidar sensor 1810b, the diffuser 136 can be engineered to spread the light emitted by the emitter array over a wide angle (e.g., 180 degrees). In each of the lidar sensors 1810a and 1810b, the same emitter array, the same pixel array and the same controller, etc. can be used thus simplifying the manufacture of multiple different lidar sensors tailored for different purposes. Any or all of lidar sensors 1810a-1910d can incorporate the circuits, methods, and apparatus that can provide detector arrays that are able to avoid or limit saturation of SPAD devices from both ambient and reflected light while maintaining sufficient sensitivity for generating a lidar image as described herein.

### 13. Additional Embodiments

In the above detailed description, numerous specific details are set forth to provide a thorough understanding of embodiments of the present disclosure. However, it will be understood by those skilled in the art that the present disclosure can be practiced without these specific details. For example, while various embodiments set forth above described can use SPAD devices, other detectors can be improved by embodiments of the present invention. As another example, some of the embodiments discussed above include a specific number of regions or diodes in a SPAD device. It is to be understood that those embodiments are for illustrative purposes only and embodiments are not limited to any particular number of regions or diodes in a SPAD device.

Additionally, in some instances, well-known methods, procedures, components, and circuits have not been described in detail so as not to obscure the present disclosure. It is intended that all embodiments disclosed herein can be implemented separately or combined in any way and/or combination. Aspects described with respect to one embodiment can be incorporated in different embodiments although not specifically described relative thereto. That is, all embodiments and/or features of any embodiments can be combined in any way and/or combination.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A single-photon avalanche diode (SPAD) device comprising:
a p-type epitaxial layer forming a common anode;
a first n-type cathode region formed in the p-type epitaxial layer;
a second n-type cathode region formed in the p-type epitaxial layer;
a first guard ring between the first n-type cathode region and the second n-type cathode region; and
a second guard ring around the first n-type cathode region and the second n-type cathode region.

2. The SPAD device of claim 1 wherein the first n-type cathode region and second n-type cathode region are implanted in a top surface of the p-type epitaxial layer.

3. The SPAD device of claim 2 wherein the first n-type cathode region has a disk shape and the second n-type cathode region has an annular shape formed around the first n-type cathode region.

4. The SPAD device of claim 3 wherein the first guard ring is formed of a first p-type region and the second guard ring is formed of a second p-type region.

5. The SPAD device of claim 3 wherein the p-type epitaxial layer is a graded layer having an increasing level of dopants near the first n-type cathode region and the second n-type cathode region.

6. The SPAD device of claim 3 further comprising a capacitor deep trench isolation channel around the second n-type cathode region.

7. The SPAD device of claim 1 further comprising a n-type handle wafer, wherein the p-type epitaxial layer is grown on the n-type handle wafer.

8. A single-photon avalanche diode (SPAD) device comprising:
an epitaxial layer comprising a first dopant and forming a common anode;
a first implant region comprising a second dopant and forming a first cathode;
a second implant region comprising the second dopant and forming a second cathode; and
a third implant region between the first implant region and the second implant region and forming a guard ring.

9. The SPAD device of claim 8 wherein the guard ring comprises the first dopant.

10. The SPAD device of claim 8 wherein the guard ring comprises a shallow trench.

11. The SPAD device of claim 8 wherein the first dopant is a p-type dopant and the second dopant is an n-type dopant.

12. The SPAD device of claim 8 wherein the first implant region has a disk shape and the second implant region has an annular shape formed around the first implant region.

13. The SPAD device of claim 8 wherein the second implant region has a notched rectangular shape and the first implant region is inset in the notch of the rectangular shape.

14. The SPAD device of claim 8 wherein the epitaxial layer is grown on a handle wafer.

15. A method of manufacturing a single-photon avalanche diode (SPAD) device, the method comprising:
receiving a handle wafer;
growing a p-type epitaxial layer on the handle wafer to form a common anode;
implanting a first n-type region in the p-type epitaxial layer to form a first cathode;
implanting a second n-type region in the p-type epitaxial layer to form a second cathode;
implanting a third region between the first n-type region and the second n-type region to form a first guard ring; and
implanting a fourth region around the first n-type region and the second n-type region to form a second guard ring.

16. The method of claim 15 further comprising forming a deep trench isolation channel around the fourth region.

17. The method of claim 16 wherein the first n-type region and the second n-type region are implanted in a surface of the p-type epitaxial layer.

18. The method of claim 17 wherein the first n-type region is implanted having a disk shape and the second n-type region is implanted having a an annular shape around the first n-type region.

19. The method of claim 17 further comprising removing the handle wafer.

20. The method of claim 19 wherein the handle wafer is removed by back-lapping.
